(19) United States
(12) Patent Application Publication
(10) Pub. No.: US 2025/0208999 A1
(43) Pub. Date: Jun. 26, 2025

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Hiromichi GODO, Isehara, Kanagawa (JP); Yoshiyuki KUROKAWA, Sagamihara, Kanagawa (JP); Satoru OHSHITA, Hadano, Kanagawa (JP)

(21) Appl. No.: 18/849,140

(22) PCT Filed: Apr. 6, 2023
(86) PCT No.: PCT/IB2023/053511

§ 371 Date: Sep. 20, 2024

(30) Foreign Application Priority Data
Apr. 15, 2022 (JP) 2022-067525

(51) Int. Cl. G06F 12/0806

(52) U.S. Cl. CPC G06F 12/0806; G06F 2212/60

(57) ABSTRACT

A novel semiconductor device is provided. The semiconductor device includes a first cache, a second cache, a cache controller, and a core. The cache controller has a function of controlling data for performing program processing to be stored in the second cache in the case where the temperature around or inside the core is higher than or equal to a predetermined temperature threshold value, and controlling the data for performing program processing to be stored in the first cache in the case where the temperature around or inside the core is lower than the predetermined temperature threshold value.

### TECHNICAL FIELD

One embodiment of the present invention relates to a semiconductor device.

Note that one embodiment of the present invention is not limited to the above technical field. The technical field of one embodiment of the invention disclosed in this specification and the like relates to an object, a method, a driving method, or a manufacturing method. Alternatively, one embodiment of the present invention relates to a process, a machine, manufacture, or a composition of matter. Specific examples of the technical field of one embodiment of the present invention disclosed in this specification and the like include a semiconductor device, a display apparatus, a light-emitting apparatus, a power storage device, an optical device, an imaging device, a lighting device, an arithmetic device, a control device, a memory device, an input device, an output device, an input/output device, a signal processing device, an electronic computer, an electronic appliance, driving methods thereof, and manufacturing methods thereof.

### BACKGROUND ART

In recent years, semiconductor devices have been developed; an LSI, a CPU (Central Processing Unit), a memory, and the like have been mainly used for semiconductor devices, for example. A CPU is an aggregation of semiconductor elements; the CPU includes a semiconductor integrated circuit formed into a chip by processing a semiconductor wafer, and is provided with an electrode that is a connection terminal. A semiconductor circuit (IC chip) of an LSI, a CPU, a memory, or the like is mounted on a circuit board (e.g., a printed wiring board) to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display apparatus (also simply referred to as a display apparatus). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, Patent Document 1 discloses a low-power-consumption CPU and the like utilizing a feature of a low leakage current of the transistor including an oxide semiconductor. Furthermore, for example, Patent Document 2 discloses a memory device and the like that can retain stored contents for a long time by utilizing a feature of a low leakage current of the transistor including an oxide semiconductor.

In recent years, demand for an integrated circuit with higher density has risen with reductions in size and weight of electronic appliances. In addition, an improvement of productivity of a semiconductor device including an integrated circuit is desired. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film.

### REFERENCES

### Patent Documents

[Patent Document 1] Japanese Published Patent Application No. 2012-257187

[Patent Document 2] Japanese Published Patent Application No. 2011-151383

[Patent Document 3] PCT International Publication No. 2021/053473

### Non-Patent Document

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

A CPU generally includes a core performing program processing and a cache memory in which data for performing program processing is stored. In terms of operating speed, an SRAM (Static Random Access Memory) formed using Si transistors (transistors each including silicon in their channel formation regions) is generally used as the cache memory. The cache memory is preferably provided near the core in order to perform data transmission and reception with the core at high speed. Thus, the cache memory is likely to be affected by heat generation of the core. For example, the SRAM used in the cache memory is affected by heat generation of the core, which decreases the operating speed.

An object of one embodiment of the present invention is to provide a semiconductor device with improved operating speed. Another object is to provide a semiconductor device in which a decrease in operating speed due to an increase in temperature is inhibited. Another object is to provide a semiconductor device with reduced power consumption. Another object is to provide a downsized semiconductor device. Another object is to provide a highly integrated semiconductor device. Another object is to provide a novel semiconductor device.

Note that the objects listed above do not preclude the existence of other objects. Note that, in one embodiment of the present invention, there is no need to achieve all these objects listed above. Objects other than objects listed above are apparent from the description of the specification, the drawings, the claims, and the like and objects other than objects listed above can be derived from the description of the specification, the drawings, the claims, and the like.

### Means for Solving the Problems

(1)

One embodiment of the present invention is a semiconductor device including a first cache, a second cache, a cache controller, and a core. The core has a function of performing program processing. The cache controller has a function of performing control to store data for performing the program processing in the second cache in the case where the temperature around or inside the core is higher than or equal to a predetermined temperature threshold value. The cache controller has a function of performing control to store the data for performing the program processing in the first cache in the case where the temperature around or inside the core is lower than the predetermined temperature threshold value.

(2)

In the above (1), the first cache may include a Si transistor, and the second cache may include an OS transistor.

(3)

In the above (2), the semiconductor device may include a substrate, a layer over the substrate, and a die over the substrate. The core may be provided over the substrate. Part of the first cache may be provided in the layer. Part of the second cache may be provided in the die. The layer may be electrically connected to the substrate through a via hole formed between the substrate and the layer. The die is electrically connected to the substrate by bonding a first electrode formed on the substrate and a second electrode formed on the die to each other.

(4)

In the above (2), the semiconductor device may include a substrate, a layer over the substrate, and a die over the layer. The core may be provided over the substrate. Part of the first cache may be provided in the layer. Part of the second cache may be provided in the die. The layer may be electrically connected to the substrate through a via hole formed between the substrate and the layer. The die is electrically connected to the layer by bonding a first electrode formed on the layer and a second electrode formed on the die to each other.

### Effect of the Invention

One embodiment of the present invention can provide a semiconductor device with improved operating speed. Another embodiment of the present invention can provide a semiconductor device in which a decrease in operating speed due to an increase in temperature is inhibited. Another embodiment of the present invention can provide a semiconductor device with reduced power consumption. Another embodiment of the present invention can provide a downsized semiconductor device. Another embodiment of the present invention can provide a highly integrated semiconductor device. Another embodiment of the present invention can provide a novel semiconductor device.

Note that the effects listed above do not preclude the presence of other effects. Note that one embodiment of the present invention does not necessarily achieve all the effects listed above. Effects other than the effects listed above are apparent from the description of the specification, the drawings, the claims, and the like and effects other than the effects listed above can be derived from the description of the specification, the drawings, the claims, and the like.

### BRIEF DESCRIPTION OF THE DRAWINGS

FIG. 1 is a diagram illustrating a structure example of a semiconductor device.

FIG. 2 is a diagram illustrating a structure example of a semiconductor device.

FIG. 3 is a diagram illustrating a structure example of a semiconductor device.

FIG. 4 is a diagram illustrating a structure example of a memory device.

FIG. 5A to FIG. 5F are diagrams each illustrating a structure example of a memory circuit.

FIG. 6 is a flowchart showing an operation example of a semiconductor device.

FIG. 7A and FIG. 7B are flowcharts each showing an operation example of a semiconductor device.

FIG. 8A and FIG. 8B are flowcharts each showing an operation example of a semiconductor device.

FIG. 9 is a diagram illustrating a structure example of a semiconductor device.

FIG. 10 is a diagram illustrating a structure example of a semiconductor device.

FIG. 11 is a diagram illustrating a structure example of a semiconductor device.

FIG. 12A to FIG. 12C are diagrams illustrating structure examples of a semiconductor device.

FIG. 13 is a diagram illustrating a structure example of a memory portion.

FIG. 14A is a diagram illustrating a structure example of a memory layer. FIG. 14B is a diagram illustrating an equivalent circuit of the memory layer.

FIG. 15 is a diagram illustrating a structure example of a memory portion.

FIG. 16A is a diagram illustrating a structure example of a memory layer. FIG. 16B is a diagram illustrating an equivalent circuit of the memory layer.

FIG. 17A and FIG. 17B are diagrams illustrating a structure example of a semiconductor device.

FIG. 18A to FIG. 18F are diagrams each illustrating a structure example of an electronic appliance.

### MODE FOR CARRYING OUT THE INVENTION

In this specification and the like, a semiconductor device refers to a device that utilizes semiconductor characteristics, and means a circuit including a semiconductor element (e.g., a transistor, a diode, or a photodiode) or a device including the circuit, for example. The semiconductor device also refers to all devices that can function by utilizing semiconductor characteristics. For example, an integrated circuit, a chip including an integrated circuit, and an electronic component including a chip in a package are examples of the semiconductor device. For example, a display apparatus, a light-emitting apparatus, an imaging device, an arithmetic device, a control device, a memory device, a signal processing device, an electronic computer, an electronic appliance, and the like themselves might be semiconductor devices, or might include semiconductor devices.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

Here, the expression “X and Y are electrically connected” means the case where electric signals can be transmitted and received between X and Y when an object having any electric action is present between X and Y. For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit (e.g., a step-up circuit or a step-down circuit) or a level shifter circuit for changing the potential level of a signal); a voltage source; a current source; a switch circuit; an amplifier circuit (e.g., a circuit that can increase signal amplitude, the current amount, or the like, an operational amplifier, a differential amplifier circuit, a source follower circuit, or a buffer circuit); a signal generation circuit; a memory circuit; or a control circuit) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (sometimes called one of a first terminal and a second terminal in this specification and the like) of a transistor, and a drain (sometimes called the other of the first terminal and the second terminal in this specification and the like) of the transistor are electrically connected to each other, and X, the source of the transistor, the drain of the transistor, and Y are electrically connected to each other in this order”. Alternatively, it can be expressed as “a source of a transistor is electrically connected to X; a drain of the transistor is electrically connected to Y; and X, the source of the transistor, the drain of the transistor, and Y are electrically connected to each other in this order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression similar to the above examples, a source and a drain of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: the wiring and the electrode. Thus, electrical connection in this specification and the like includes, in its category, such a case where one conductive film has functions of a plurality of components.

In this specification and the like, as a “resistor”, a circuit element, a wiring, or the like having a resistance value higher than 0 Ω can be used, for example. Accordingly, in this specification and the like, examples of the “resistor” include a wiring having a resistance value, a transistor in which current flows between its source and drain, a diode, and a coil. Thus, the term “resistor” can be replaced with the terms “resistance”, “load”, “region having a resistance value”, or the like. Conversely, the terms “resistance”, “load”, and “region having a resistance value” can be replaced with the term “resistor”, or the like. The resistance value can be, for example, preferably higher than or equal to 1 mΩ and lower than or equal to 10 Ω, further preferably higher than or equal to 5 mΩ and lower than or equal to 5 Ω, still further preferably higher than or equal to 10 mΩ and lower than or equal to 1 Ω. As another example, the resistance value may be higher than or equal to 1 Ω and lower than or equal to 1×10⁹ Ω.

In the case where a wiring is used as a resistor, the resistance value of the resistor is sometimes determined depending on the length of the wiring. Alternatively, a conductor with resistivity different from that of a conductor used as a wiring is sometimes used as a resistor. Alternatively, in the case where a semiconductor is used as a resistor, the resistance value of the resistor is sometimes determined by doping the semiconductor with an impurity.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Thus, in this specification and the like, a “capacitor” is not limited to only a circuit element that has a pair of electrodes and a dielectric between the electrodes. A “capacitor” includes, for example, parasitic capacitance generated between wirings, gate capacitance generated between a gate and one of a source and a drain of a transistor, and the like. The term “capacitor”, “parasitic capacitance”, “gate capacitance”, or the like can be replaced with the term “capacitance” and the like, for example. Conversely, the term “capacitance” can be replaced with the term “capacitor”, “parasitic capacitance”, “gate capacitance”, or the like, for example. The term “a pair of electrodes” of a “capacitor” can be replaced with “a pair of conductors”, “a pair of conductive regions”, “a pair of regions”, or the like, for example. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

A transistor in this specification and the like includes three terminals including a gate (also referred to as a gate terminal, a gate region, or a gate electrode), a source (also referred to as a source terminal, a source region, or a source electrode), and a drain (also referred to as a drain terminal, a drain region, or a drain electrode). The transistor includes a region where a channel is formed (also referred to as a channel formation region) between the drain and the source. The transistor can allow current to flow between the source and the drain through the channel formation region. The channel formation region is a region through which the current mainly flows. The gate is a control terminal for controlling the amount of current flowing to the channel formation region between the source and the drain. Two terminals functioning as the source and the drain are input/output terminals of the transistor.

Note that one of the two input/output terminals serves as the source and the other serves as the drain depending on the conductivity type (n-channel type or p-channel type) of the transistor and the levels of potentials supplied to the three terminals of the transistor. In some cases, the function of the source and the function of the drain are replaced with each other when the direction of current flow is changed in a circuit operation, for example. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relationship of a transistor.

Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, each of the gates may be referred to as a first gate, a second gate, or a third gate, for example, in this specification and the like.

Note that in this specification and the like, a transistor having a multi-gate structure having two or more gate electrodes can be used as the transistor. In a transistor having the multi-gate structure, channel formation regions are connected in series; accordingly, a plurality of transistors are connected in series. Thus, in the transistor having the multi-gate structure, the amount of off-state current can be reduced, and the withstand voltage of the transistor can be increased (the reliability can be improved). Alternatively, in the transistor having the multi-gate structure, drain-source current does not change very much even if drain-source voltage changes at the time of an operation in a saturation region, so that a flat slope of voltage-current characteristics can be obtained. The transistor having the flat slope of the voltage-current characteristics can achieve an ideal current source circuit or an active load having an extremely high resistance value. As a result, the transistor having the flat slope of the voltage-current characteristics can achieve, for example, a differential circuit, a current mirror circuit, or the like having high characteristics.

In this specification and the like, the case where a single circuit element is illustrated in a circuit diagram may indicate a case where the circuit element includes a plurality of circuit elements. For example, the case where a single resistor is illustrated in a circuit diagram may indicate a case where two or more resistors are electrically connected to each other in series. As another example, the case where a single capacitor is illustrated in a circuit diagram may indicate a case where two or more capacitors are electrically connected to each other in parallel. As another example, the case where a single transistor is illustrated in a circuit diagram may indicate a case where two or more transistors are electrically connected to each other in series and their gates are electrically connected to each other. Similarly, as another example, the case where a single switch is illustrated in a circuit diagram may indicate a case where the switch includes two or more transistors which are electrically connected to each other in series or in parallel and whose gates are electrically connected to each other.

In this specification and the like, a “node” can be referred to as a “terminal”, a “wiring”, an “electrode”, a “conductive layer”, a “conductor”, an “impurity region”, or the like depending on the circuit structure, the device structure, or the like, for example. Furthermore, a “terminal”, a “wiring”, or the like can be referred to as a “node”, for example.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values. That is, a potential supplied to a wiring, a potential applied to a circuit and the like, or a potential output from a circuit and the like, are changed with a change of the reference potential.

In this specification and the like, the terms “high-level potential” (also referred to as “H potential” or “H”) and “low-level potential” (also referred to as “L potential” or “L”) do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

In this specification and the like, “current” means a charge transfer phenomenon (electrical conduction). For example, the description “electrical conduction of positively charged particles occurs” can be rephrased as “electrical conduction of negatively charged particles occurs in the opposite direction”. Thus, unless otherwise specified, “current” in this specification and the like refers to a charge transfer phenomenon (electrical conduction) accompanied by carrier movement. Examples of a carrier here include an electron, a hole, an anion, a cation, and a complex ion. The type of carrier differs depending on current-flowing systems (e.g., a semiconductor, a metal, an electrolyte solution, or a vacuum). For example, the “direction of current” in a wiring or the like refers to the direction in which a positive carrier moves, and the amount of current is expressed as a positive value. In other words, the direction in which a negative carrier moves is opposite to the direction of current, and the amount of current is expressed as a negative value. Thus, in the case where the polarity of current (or the direction of current) is not specified in this specification and the like, the description “current flows from element A to element B” can be rephrased as “current flows from element B to element A” and the like, for example. The description “current is input to element A” and the like can be rephrased as “current is output from element A” and the like, for example.

Ordinal numbers such as “first”, “second”, and “third” in this specification and the like are used to avoid confusion among components. Thus, the ordinal numbers do not limit the number of components. In addition, the ordinal numbers do not limit the order of components. For example, a “first” component in one embodiment in this specification and the like can be referred to as a “second” component in other embodiments, the scope of claims, and the like. Furthermore, for example, a “first” component in one embodiment in this specification and the like can be omitted in other embodiments, the scope of claims, and the like.

In this specification and the like, for example, terms for describing arrangement, such as “over”, “under”, “above”, and “below” are sometimes used for convenience to describe the positional relationship between components with reference to drawings. The positional relationship between components is changed as appropriate in accordance with a direction in which each component is described. Thus, the terms for describing arrangement in this specification and the like are not limited to those and can be replaced with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°. Moreover, the expression “an insulator positioned over (on) a top surface of a conductor” can be replaced with the expression “an insulator positioned on a left surface (or a right surface) of a conductor” when the direction of a drawing illustrating these components is rotated by 90°.

The term “over” or “under” does not necessarily mean that a component is placed directly over or directly under and directly in contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, components arranged in a matrix and their positional relation are sometimes described using a term such as “row” or “column”, for example. The positional relationship between components is changed as appropriate in accordance with a direction in which each component is described. Thus, the positional relationship is not limited to the term such as “row” or “column” described in this specification and the like, and can be described with another term as appropriate depending on the situation. For example, the term “row direction” can be replaced with the term “column direction” when the direction of the diagram is rotated by 90°.

Furthermore, the term “overlap”, for example, in this specification and the like does not limit a state such as the stacking order of components. For example, the expression “electrode B overlapping with insulating layer A” does not necessarily mean the state where the electrode B is formed over the insulating layer A. The expression “electrode B overlapping with insulating layer A”, for example, does not exclude the state where the electrode B is formed under the insulating layer A and the state where the electrode B is formed on the right side (or the left side) of the insulating layer A.

The term “adjacent” or “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is provided between the insulating layer A and the electrode B.

In this specification and the like, the term “film”, “layer”, or the like can be, for example, interchanged with each other depending on the situation, in some cases. For example, the term “conductive layer” can be changed into the term “conductive film” in some cases. For another example, the term “insulating film” can be changed into the term “insulating layer” in some cases. Alternatively, for example, the term “film”, “layer”, or the like is not used and can be interchanged with another term depending on the situation, in some cases. For example, the term “conductive layer” or “conductive film” can be changed into the term “conductor” in some cases. Furthermore, the term “conductor” can be changed into the term “conductive layer” or “conductive film” in some cases. For example, the term “insulating layer” or “insulating film” can be changed into the term “insulator” in some cases. Furthermore, the term “insulator” can be changed into the term “insulating layer” or “insulating film” in some cases.

In addition, in this specification and the like, for example, the term such as “electrode”, “wiring”, or “terminal” does not limit the function of a component. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Thus, for example, an “electrode” can be part of a “wiring” or a “terminal”. Furthermore, a “terminal” can be part of a “wiring” or an “electrode”. Moreover, the term “electrode”, “wiring”, “terminal”, or the like is sometimes replaced with the term “region”, for example.

In addition, in this specification and the like, for example, the term such as “wiring”, “signal line”, or “power supply line” can be replaced with each other depending on the situation, in some cases. For example, the term “wiring” can be changed into the term “signal line” in some cases. For another example, the term “wiring” can be changed into the term “power supply line” or the like in some cases. Conversely, for example, the term “signal line”, “power supply line”, or the like can be changed into the term “wiring” in some cases. Furthermore, for example, the term “power supply line” or the like can be changed into the term “signal line” or the like in some cases. Conversely, for example, the term “signal line” or the like can be changed into the term “power supply line” or the like in some cases. Moreover, the term “potential” that is applied to a wiring can be changed into the term “signal” or the like depending on the situation, for example. Conversely, for example, the term “signal” or the like can be changed into the term “potential” in some cases.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in a “conduction state” or an “on state”. In the case where electrical continuity is not established between the two terminals, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether current flows therethrough or not. Alternatively, a switch has a function of selecting and changing a current path. For example, an electrical switch or a mechanical switch can be used as the switch. That is, a switch can be any element capable of controlling current, and is not limited to a particular element.

Note that as a kind of a switch, there is a switch which is normally in a non-conduction state and brought into a conduction state by controlling a conduction state; such a switch is referred to as an “A contact” in some cases. Furthermore, as another kind of a switch, there is a switch which is normally in a conduction state and brought into a non-conduction state by controlling a conduction state; such a switch is referred to as a “B contact” in some cases.

Examples of the electrical switch include a transistor (e.g., a bipolar transistor or a MOS transistor), a diode (e.g., a PN diode, a PIN diode, a Schottky diode, a MIM (Metal Insulator Metal) diode, a MIS (Metal Insulator Semiconductor) diode, or a diode-connected transistor), and a logic circuit in which such elements are combined. Note that in the case where a transistor operates just as a switch, there is no particular limitation on the polarity (conductivity type) of the transistor.

An example of the mechanical switch is a switch using a MEMS (micro electro mechanical systems) technology. Such a switch includes an electrode that can be moved mechanically, and selects a conduction or non-conduction state with the movement of the electrode.

Note that in the case of using a transistor as a switch, a “conduction state” or “on state” of the transistor refers to a state where a source electrode and a drain electrode of the transistor can be regarded as being electrically short-circuited or a state where current can be made to flow between the source electrode and the drain electrode. For example, the “conduction state” or the “on state” refers to a state where the voltage between the gate and the source is higher than the threshold voltage in an n-channel transistor, a state where the voltage between the gate and the source is lower than the threshold voltage in a p-channel transistor, or the like in some cases. Furthermore, a “non-conduction state”, a “cutoff state”, or an “off state” of the transistor refers to a state where the source electrode and the drain electrode of the transistor can be regarded as being electrically disconnected. For example, the “non-conduction state”, the “cutoff state”, or the “off state” refers to a state where the voltage between the gate and the source is lower than the threshold voltage in an n-channel transistor, a state where the voltage between the gate and the source is higher than the threshold voltage in a p-channel transistor, or the like in some cases.

In this specification and the like, “off-state current” of a transistor refers to current flowing between a source and a drain of the transistor in the off state (also referred to as drain current) unless otherwise specified. Note that in this specification and the like, when the transistor is in the off state, drain current and current flowing between the gate and the source or the drain (also referred to as gate leakage current) are sometimes referred to as leakage current.

In this specification and the like, the “channel length” of the transistor refers to, for example, the distance between a source and a drain in a region where a semiconductor (or a portion where current flows in a semiconductor when a transistor is in an on state) and a gate overlap with each other or the distance between the source and the drain of a region where a channel is formed in a top view of the transistor.

In this specification and the like, the “channel width” of the transistor refers to, for example, the length of a portion where a source and a drain face each other in a region where a semiconductor (or a portion where current flows in a semiconductor when a transistor is an on state) and a gate overlap with each other or the length of a portion where a source and a drain face each other in a region where a channel is formed in a top view of the transistor.

In this specification and the like, for example, the term such as “substrate”, “wafer”, or “die” does not functionally limit these components. For example, the term such as “substrate,” “wafer,” or “die,” can be interchanged with each other depending on the situation in some cases.

In this specification and the like, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

Note that in this specification and the like, the expression “level or substantially level” means that levels from a reference surface (e.g., a flat surface such as a substrate surface) are the same in a cross-sectional view. For example, in a manufacturing process of a semiconductor device, planarization treatment is performed, whereby the surface(s) of a single layer or a plurality of layers are exposed in some cases. In this case, the surfaces on which the planarization treatment is performed are at the same level from a reference surface. Note that the surfaces of a plurality of layers on which the planarization treatment is performed are not exactly level with each other in some cases, depending on a treatment apparatus, a treatment method, or a material of the treated surfaces on which the planarization treatment is performed. This case is also described with the expression “level or substantially level” in this specification and the like. For example, the expression “level or substantially level” also refers to the case where two layers (here, given as a first layer and a second layer) whose levels with respect to the reference surface are different from each other and the case where a difference between the top-surface level of the first layer and the top-surface level of the second layer is less than or equal to 20 nm.

Note that in this specification and the like, the expression “end portions are aligned or substantially aligned” means that outlines of stacked layers at least partly overlap with each other in a top view. For example, the case of processing the upper layer and the lower layer with use of the same mask pattern or mask patterns that are partly the same in a manufacturing process of a semiconductor device is included. However, in some cases, the outlines do not exactly overlap with each other and the outline of the upper layer is located inward from the outline of the lower layer or the outline of the upper layer is located outward from the outline of the lower layer. This case is also described with the expression “end portions are aligned or substantially aligned” in this specification and the like.

Note that in this specification and the like, for example, the terms “identical”, “the same”, “equal”, “uniform”, and the like (including synonyms of these words) used in describing calculation values and measurement values or in describing objects, methods, events, and the like that can be converted into calculation values or measurement values, allow for a margin of error of ±20% unless otherwise specified.

In this specification and the like, an impurity in a semiconductor refers to, for example, an element other than a main component of a semiconductor layer. For example, an element with a concentration of lower than 0.1 atomic % is an impurity. When an impurity is contained in a semiconductor, for example, the density of defect states in a semiconductor is increased, carrier mobility is decreased, or crystallinity is decreased in some cases. In the case where the semiconductor is an oxide semiconductor, examples of an impurity that changes the characteristics of the semiconductor include Group 1 elements, Group 2 elements, Group 13 elements, Group 14 elements, Group 15 elements, or transition metals other than the main components of the oxide semiconductor. Specific examples include hydrogen (included also in water), lithium, sodium, silicon, boron, phosphorus, carbon, and nitrogen. In the oxide semiconductor, oxygen vacancies (also referred to as V_{O}) are formed in the oxide semiconductor in some cases by entry of impurities, for example.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like, for example. For example, in the case where a metal oxide is used in a semiconductor layer of a transistor, the metal oxide is referred to as an oxide semiconductor in some cases. That is, when a metal oxide is used as a material that can be used for a channel formation region of a transistor that has at least one of an amplifying function, a rectifying function, and a switching function, the metal oxide can be referred to as a metal oxide semiconductor. In addition, the term “OS transistor” can also be referred to as a transistor containing a metal oxide or an oxide semiconductor.

In this specification and the like, a metal oxide containing nitrogen is also collectively referred to as a metal oxide in some cases. A metal oxide containing nitrogen may be referred to as a metal oxynitride.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined with each other as appropriate.

Embodiments described in this specification are described with reference to the drawings. Note that the embodiments can be implemented in many different modes. Thus, it will be readily understood by those skilled in the art that the modes and details can be changed in various ways without departing from the spirit and scope thereof. Therefore, the present invention should not be interpreted as being limited to the description in the embodiments. As for the drawings illustrating the embodiments, in the structures of the invention, the same reference numerals are used in common for the same portions or portions having similar functions in different drawings, and repeated description thereof is omitted in some cases. Furthermore, the same hatching pattern is used for the portions having similar functions throughout the drawings, and the portions are not especially denoted by reference numerals in some cases. Moreover, some components are omitted in a perspective view or a top view (also referred to as a “plan view”), for example for easy understanding of the drawings in some cases. The description of some hidden lines might also be omitted in the drawings. In the drawings, for example, a hatching pattern or the like is omitted in some cases.

In addition, in the drawings and the like in this specification, the size, the layer thickness, or the region is exaggerated for clarity in some cases. Thus, the drawings are not necessarily limited to the drawings with the illustrated size, aspect ratio, and the like, for example. Note that the drawings schematically illustrate ideal examples, and embodiments of the present invention are not limited to shapes, values, and the like illustrated in the drawings, for example.

For example, in the drawings and the like in this specification, variation in signal, voltage, or current due to noise or variation in signal, voltage, or current due to difference in timing can be included.

For example, in the drawings and the like in this specification, in the actual manufacturing process, a layer, a resist mask, or the like might be unintentionally reduced in size by treatment such as etching, which might not be reflected in the drawings for easy understanding.

In the drawings and the like in this specification, when a block diagram is used, components of the present invention are classified on the basis of the functions, and shown as blocks independent of one another in some cases. However, when an actual circuit and the like are illustrated as a block diagram, for example, it is difficult to separate components on the basis of the functions, and there is such a case where one circuit is associated with a plurality of functions or a case where a plurality of circuits are associated with one function. Therefore, blocks in the block diagrams are not limited by any of the components described in this specification and the like, and can be changed appropriately depending on situations.

In the drawings and the like in this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals, for example.

### Embodiment 1

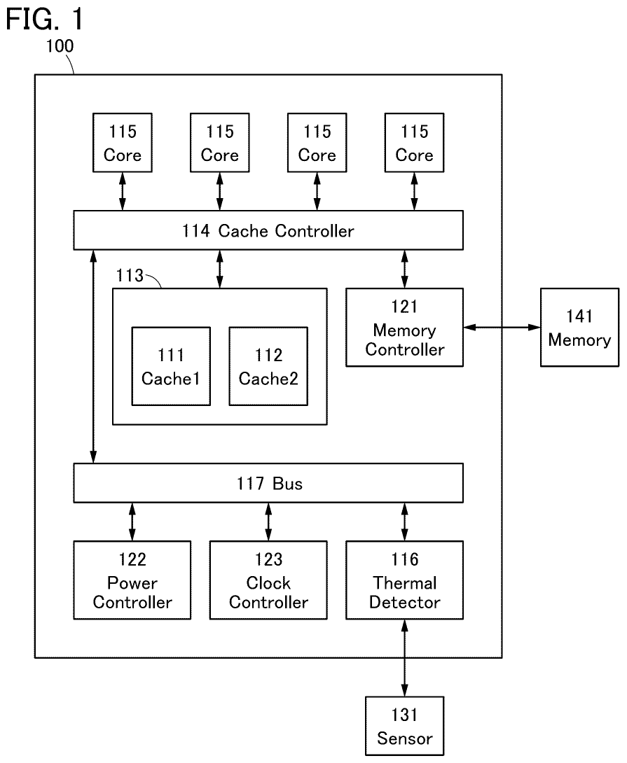

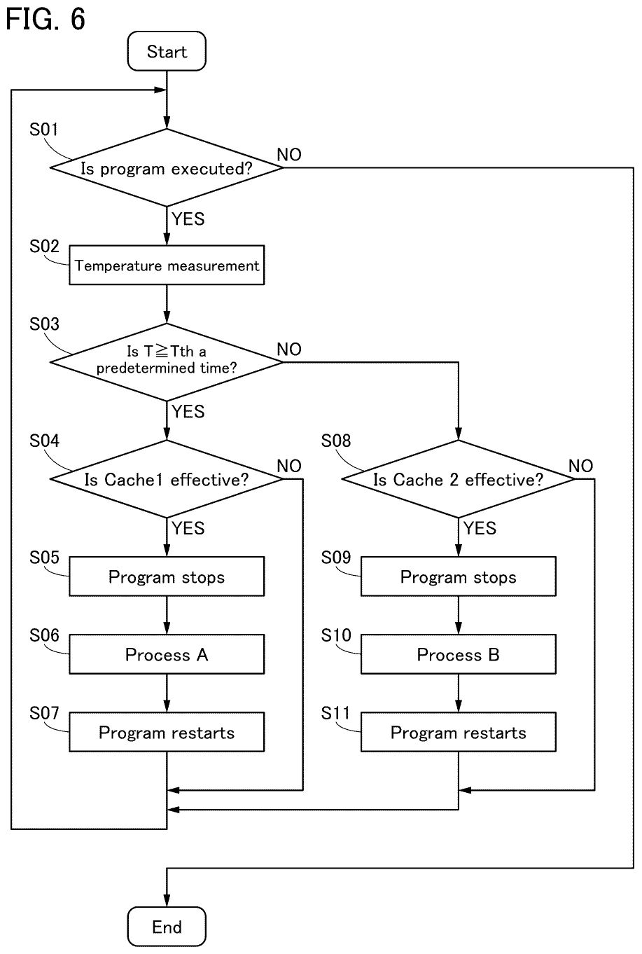

Structure examples of a semiconductor device of one embodiment of the present invention will be described with reference to FIG. 1 to FIG. 5. Operation examples of the semiconductor device of one embodiment of the present invention will be described with reference to FIG. 6 to FIG. 8.

Note that the semiconductor device of one embodiment of the present invention may be suitably used as part of a central processing unit (CPU), for example.

### <Structure Example>

FIG. 1 is a block diagram illustrating a structure example of a semiconductor device 100 of one embodiment of the present invention. As illustrated in FIG. 1, the semiconductor device 100 includes a cache portion 113, a cache controller 114, a core 115, a thermal detector 116, a bus 117, a memory controller 121, a power controller 122, and a clock controller 123. The cache portion 113 includes a first cache 111 (Cache1) and a second cache 112 (Cache2).

Note that the semiconductor device 100 can include one or more of cores 115. For example, the semiconductor device 100 illustrated in FIG. 1 includes four cores 115.

As illustrated in FIG. 1, a temperature sensor 131 (Sensor) and a memory 141 (Memory) are provided around the semiconductor device 100. Note that one or both of the temperature sensor 131 and the memory 141 may be provided inside the semiconductor device 100.

The core 115 has a function of performing program processing. In addition, the core 115 has a function of transmitting a read request to the cache controller 114 in order to obtain data for performing the program processing. The read request includes an address of the memory 141. Note that in the case where the semiconductor device 100 is used as part of the CPU, the core 115 can have a function of an arithmetic device (also referred to as a processor core).

The memory 141 has a function of storing data for performing program processing. Note that in the case where the semiconductor device 100 is used as part of the CPU, the memory 141 can have a function of a main memory device (also referred to as a main memory). A DRAM (Dynamic Random Access Memory) can be used as the memory 141, for example.

The memory controller 121 has a function of controlling reading or writing of data from/to the memory 141 based on the request from the cache controller 114.

The cache portion 113 has a function of storing data for performing program processing and the address of the memory 141 where the data is stored, in the first cache 111 or the second cache 112. Note that in the case where the semiconductor device 100 is used as part of the CPU, the cache portion 113 can have a function of a buffer memory device (also referred to as a cache memory). Therefore, the cache portion 113 is preferably provided near the core 115 in order to perform data transmission and reception with the core 115 at high speed.

Note that in the case where the semiconductor device 100 is used as a CPU including a primary cache to an L-th cache (L is an integer greater than or equal to 2), the cache portion 113 can have a function of an L-th cache, for example. Alternatively, for example, the cache portion 113 may have a function of an L−1-th cache and the memory 141 may have a function of an L-th cache.

In the case where the cache controller 114 receives the read request from the core 115 and the data corresponding to an address included in the request exists in the cache portion 113, the cache controller 114 has a function of reading the data from the cache portion 113 and outputting the data to the core 115. Alternatively, in the case where the cache controller 114 receives the read request from the core 115 and the data corresponding to the address included in the request does not exist in the cache portion 113, the cache controller 114 has a function of reading the data from the memory 141 through the memory controller 121, outputting the data to the core 115, and storing the data in the cache portion 113.

In addition, the cache controller 114 has a function of transmitting an interrupt request to the core 115 in order to stop or restart program processing.

The first cache 111 and the second cache 112 are formed using transistors having different temperature characteristics. As the first cache 111, an SRAM (Static Random Access Memory) including Si transistors (transistors each including silicon in their channel formation regions) can be used, for example. As the second cache 112, an OS memory including OS transistors (transistors each including an oxide semiconductor in their channel formation regions) can be used, for example. The OS memory is a memory that can hold stored data for a long time by using OS transistors with extremely low off-state current.

The Si transistor has higher operating speed than the OS transistor. Si transistors can form a CMOS circuit (e.g., a circuit that operates complementarily, a CMOS logic gate, or a CMOS logic circuit) by electrically connecting a gate of an n-channel Si transistor and a gate of a p-channel Si transistor. The circuit composed of Si transistors can increase operating speed and reduce power consumption in a steady state. Therefore, the Si transistor is preferably used in, for example, the cache controller 114, the core 115, the thermal detector 116, the memory controller 121, the power controller 122, the clock controller 123, and the like in addition to the first cache 111.

The OS transistor has a feature that the off-state current (current flowing between a source and a drain when the transistor is in an off state) is extremely low because the band gap of an oxide semiconductor where a channel is formed is greater than or equal to 2 eV. The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that, the off-state current value per micrometer of channel width of the Si transistor at room temperature is higher than or equal to 1 fA (1×10⁻¹⁵ A) and lower than or equal to 1 pA (1×10⁻¹² A). In other words, the off-state current of the OS transistor is lower than that of the Si transistor by approximately ten orders of magnitude.

The off-state current of the OS transistor hardly increases even in a high-temperature environment. Specifically, the off-state current hardly increases even at an environmental temperature higher than or equal to room temperature and lower than or equal to 200° C. Furthermore, the on-state current of the OS transistor is unlikely to decrease even in a high-temperature environment. Meanwhile, the on-state current of the Si transistor decreases in a high-temperature environment. That is, the OS transistor has a higher on-state current than the Si transistor in a high-temperature environment. In the OS transistor, the ratio between on-state current and off-state current is large even at an environmental temperature higher than or equal to 125° C. and lower than or equal to 150° C.; thus, a favorable switching operation can be performed. Thus, the semiconductor device including the OS transistor can operate stably and have high reliability even in a high-temperature environment.

Thus, the first cache 111 including Si transistors operates at a higher speed than the second cache 112 including OS transistors at a lower temperature. Meanwhile, with the increase in temperature, the operating speed of the first cache 111 decreases and thus the first cache 111 operates slower than the second cache 112 in some cases.

The first cache 111 and the second cache 112 are preferably provided near the core 115 in order to perform data transmission and reception with the core 115 at high speed. Thus, the first cache 111 and the second cache 112 are likely to be affected by heat generation of the core 115.

In other words, when the heat generated in the core 115 is transferred to the first cache 111 and the second cache 112 in performing the program processing, the temperature increases; thus, the first cache 111 operates slower than the second cache 112 in some cases. Thus, the cache controller 114 controls the cache portion 113 in accordance with the temperature such that either the first cache 111 or the second cache 112 whose operating speed is higher is used.

The cache controller 114 has a function of controlling the use of the first cache 111 and the second cache 112 to be switched in accordance with the temperature around or inside the core 115. Thus, the operating speed of the semiconductor device 100 can be improved. In addition, a decrease in operating speed of the semiconductor device 100 due to an increase in temperature can be inhibited.

The semiconductor layer of the OS transistor preferably contains at least one of indium and zinc. The semiconductor layer of the OS transistor preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, the element M is preferably one or more kinds selected from gallium, aluminum, yttrium, and tin.

It is particularly preferable to use an oxide containing indium (In), gallium (Ga), and zinc (Zn) (also referred to as “IGZO”) for the semiconductor layer. Alternatively, an oxide containing indium (In), aluminum (Al), and zinc (Zn) (also referred to as “IAZO”) may be used for the semiconductor layer. Further alternatively, an oxide containing indium (In), aluminum (Al), gallium (Ga), and zinc (Zn) (also referred to as “IAGZO”) may be used for the semiconductor layer.

When the semiconductor layer is In-M-Zn oxide, the atomic ratio of In is preferably greater than or equal to the atomic ratio of M in the In-M-Zn oxide. Examples of the atomic ratio of the metal elements in such In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. The atomic ratio of In may be smaller than the atomic ratio of M in the In-M-Zn oxide. Examples of the atomic ratio of the metal elements in such an In-M-Zn oxide include In:M:Zn=1:3:2 or a composition in the neighborhood thereof or In:M:Zn=1:3:4 or a composition in the neighborhood thereof. Note that a composition in the neighborhood includes the range of ±30% of an intended atomic ratio.

The thermal detector 116 has a function of measuring temperature with the use of the temperature sensor 131. The thermal detector 116 has a function of transmitting information on whether the measured temperature is higher than or equal to a predetermined temperature threshold value to the cache controller 114 through the bus 117.

Note that the thermal detector 116 preferably includes an analog-to-digital converter (ADC). When the thermal detector 116 includes an ADC, a temperature sensor that outputs an analog signal can be used as the temperature sensor 131.

The temperature sensor 131 has a function of outputting a signal corresponding to a temperature to the thermal detector 116. When the temperature sensor 131 is provided around the core 115, the temperature sensor 131 outputs a signal corresponding to the temperature around the core 115 to the thermal detector 116. Alternatively, when the temperature sensor 131 is provided inside the core 115, a signal corresponding to the temperature inside the core 115 may be output to the thermal detector 116. As the temperature sensor 131, a resistance thermometer (e.g., platinum, nickel, or copper), a thermistor, a thermocouple, an IC temperature sensor, or the like is used, for example. Alternatively, the temperature sensor 131 may have a structure using a semiconductor temperature sensor (e.g., a silicon diode temperature sensor) or a structure using a bandgap circuit, for example.

The cache controller 114 has a function of receiving information on whether the measured temperature is higher than or equal to a predetermined temperature threshold value and controlling the cache portion 113 in accordance with the information. That is, the cache controller 114 has a function of performing control such that the second cache 112 is used in the case where the temperature of the core 115 is higher than or equal to the predetermined temperature threshold value, and the first cache 111 is used in the case where the temperature of the core 115 is lower than the predetermined temperature threshold value.

Note that in the case where the semiconductor device 100 includes a plurality of cores 115 as illustrated in FIG. 1, for example, the thermal detector 116 uses the temperature sensor 131 provided around or inside each of the plurality of cores 115 to measure each temperature, and the average value, the median value, or the maximum value of each of the measured temperature is set as the temperature around or inside the core 115. Alternatively, for example, the thermal detector 116 may use the temperature sensor 131 provided around or inside one core 115 selected from the plurality of cores 115 to measure the temperature, and the measured temperature may be set as the temperature around or inside the core 115.

For example, the thermal detector 116 may measure temperature using the temperature sensor 131 provided in one or both of the periphery or the inside of the first cache 111 and the periphery or the inside of the second cache 112.

The bus 117 has a function of a transmission path that transmits and receives data, a request, a command, a signal, or the like between components of the semiconductor device 100, for example.

The power controller 122 has a function of controlling supply of power (e.g., a potential VSS and a potential VDD) to the components of the semiconductor device 100. The potential VSS may be a ground potential, for example. The potential VDD is a potential higher than the potential VSS, i.e., a potential at which a potential difference between the potential VDD and the potential VSS is higher than or equal to the threshold voltage of the transistor. The power controller 122 can stop the power supply to the first cache 111 by receiving a command for stopping the power supply to the first cache 111, for example. Furthermore, the power controller 122 can stop the power supply to the second cache 112 by receiving a command for stopping the power supply to the second cache 112, for example.

The clock controller 123 has a function of controlling supply of a clock signal (e.g., a signal CLK) to components of the semiconductor device 100. For example, the clock controller 123 can stop supply of a clock signal to the first cache 111 by receiving a command for stopping supply of the clock signal to the first cache 111. For example, the clock controller 123 can stop supply of a clock signal to the second cache 112 by receiving a command for stopping supply of the clock signal to the second cache 112.

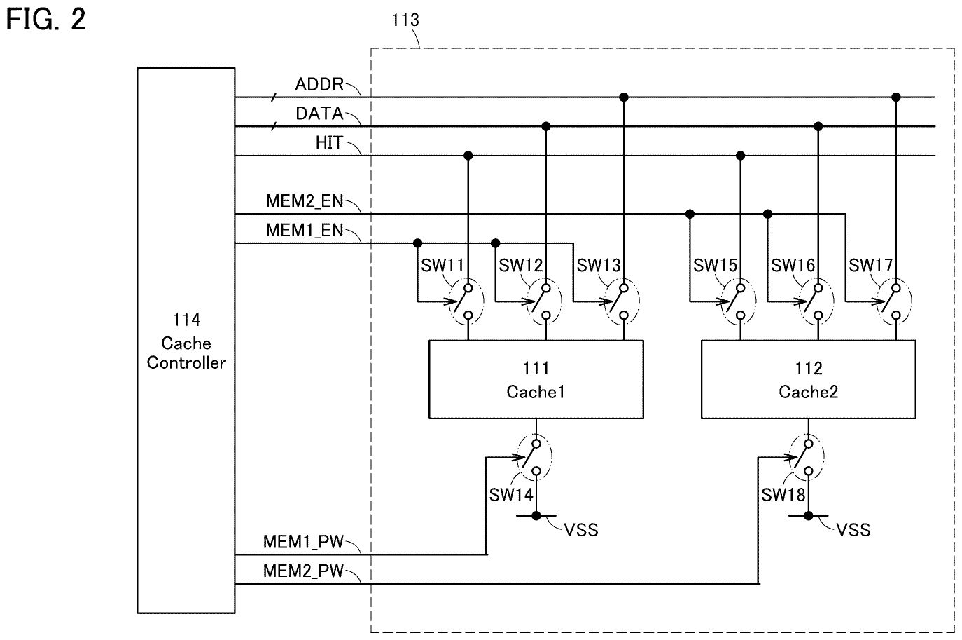

FIG. 2 is a circuit diagram illustrating a detailed structure example around the cache portion 113 in the semiconductor device 100 illustrated in FIG. 1. As illustrated in FIG. 2, the cache portion 113 includes a switch SW11, a switch SW12, a switch SW13, a switch SW14, a switch SW15, a switch SW16, a switch SW17, and a switch SW18 in addition to the above-described first cache 111 and second cache 112.

The cache controller 114 can transmit and receive a signal ADDR, a signal DATA, a signal HIT, a signal MEM1_EN, a signal MEM1_PW, a signal MEM2_EN, and a signal MEM2_PW to and from the cache portion 113 (the first cache 111 or the second cache 112) . The signal ADDR is a signal indicating the address of the memory 141. The signal DATA is data for performing program processing in the core 115. The signal HIT is a signal indicating whether the data corresponding to an address of the signal ADDR exists in the first cache 111 or the second cache 112.

Note that FIG. 2 illustrates a structure in which the cache portion 113 includes one switch SW13 and one switch SW17 for simple description; however, a plurality of switches SW13 and a plurality of switches SW17 are provided in accordance with the number of bits of the signal ADDR. In addition, a structure in which the cache portion 113 includes one switch SW12 and one switch SW16 is illustrated; however, a plurality of switches SW12 and a plurality of switches SW16 are provided in accordance with the number of bits of the signal DATA.

When the cache controller 114 receives a read request from the core 115, first, the cache controller 114 transmits the signal ADDR to the first cache 111 or the second cache 112. When the first cache 111 or the second cache 112 receives the signal ADDR from the cache controller 114, the first cache 111 or the second cache 112 determines whether data corresponding to the address of the memory 141 indicated by the signal ADDR is stored. In the case where the data is stored, the signal DATA that is the data and the signal HIT indicating that the data exists (also referred to as a cache hit) are output to the cache controller 114. In the case where the data is not stored, the signal HIT indicating that the data does not exist (also referred to as a cache miss) is output to the cache controller 114.

Each of the switch SW11 to the switch SW13 has a function of being turned on or turned off in accordance with the signal MEM1_EN. The switch SW14 has a function of being turned on or turned off in accordance with the signal MEM1_PW. Each of the switch SW15 to the switch SW17 has a function of being turned on or turned off in accordance with the signal MEM2_EN. The switch SW18 has a function of being turned on or turned off in accordance with the signal MEM2_PW.

When the switch SW14 is turned on, the potential VSS is supplied to the first cache 111. In the case where the switch SW14 is in the on state, when the switch SW11 is turned on, the signal HIT can be transmitted and received between the cache controller 114 and the first cache 111. When the switch SW12 is turned on, the signal DATA can be transmitted and received between the cache controller 114 and the first cache 111. When the switch SW13 is turned on, the signal ADDR can be transmitted and received between the cache controller 114 and the first cache 111.

That is, in the case where the switch SW11 to the switch SW14 are all in the on state, the signal ADDR, the signal DATA, and the signal HIT can be transmitted and received between the cache controller 114 and the first cache 111. In this embodiment and the like, this state is referred to as a state where the first cache 111 is effective. In the case where at least one of the switch SW11 to the switch SW14 is in the off state, the signal ADDR, the signal DATA, and the signal HIT are not transmitted and received between the cache controller 114 and the first cache 111. In this embodiment and the like, such a state is referred to as a state where the first cache 111 is ineffective.

When the switch SW18 is turned on, the potential VSS is supplied to the second cache 112. In the case where the switch SW18 is in the on state, when the switch SW15 is turned on, the signal HIT can be transmitted and received between the cache controller 114 and the second cache 112. When the switch SW16 is turned on, the signal DATA can be transmitted and received between the cache controller 114 and the second cache 112. When the switch SW17 is turned on, the signal ADDR can be transmitted and received between the cache controller 114 and the second cache 112.

That is, in the case where the switch SW15 to the switch SW18 are all in the on state, the signal ADDR, the signal DATA, and the signal HIT can be transmitted and received between the cache controller 114 and the second cache 112. In this embodiment and the like, this state is referred to as the state where the second cache 112 is effective. In the case where at least one of the switch SW15 to the switch SW18 is in the off state, the signal ADDR, the signal DATA, and the signal HIT are not transmitted and received between the cache controller 114 and the second cache 112. In this embodiment and the like, such a state is referred to as a state where the second cache 112 is ineffective.

The cache controller 114 can control the cache portion 113 so that one of the first cache 111 and the second cache 112 is brought into an effective state and the other is brought into an ineffective state by the signal MEM1_EN, the signal MEM1_PW, the signal MEM2_EN, and the signal MEM2_PW. In this embodiment and the like, the case where the first cache 111 is in an effective state and the second cache 112 is in an ineffective state is referred to as a first cache mode. The case where the second cache 112 is in an effective state and the first cache 111 is in an ineffective state is referred to as a second cache mode.

Accordingly, the cache controller 114 has a function of receiving information on whether the temperature around or inside the core 115 is higher than or equal to a predetermined temperature threshold value from the thermal detector 116 and controlling the cache portion 113 so that the cache portion 113 operates in the first cache mode or the second cache mode in accordance with the information.

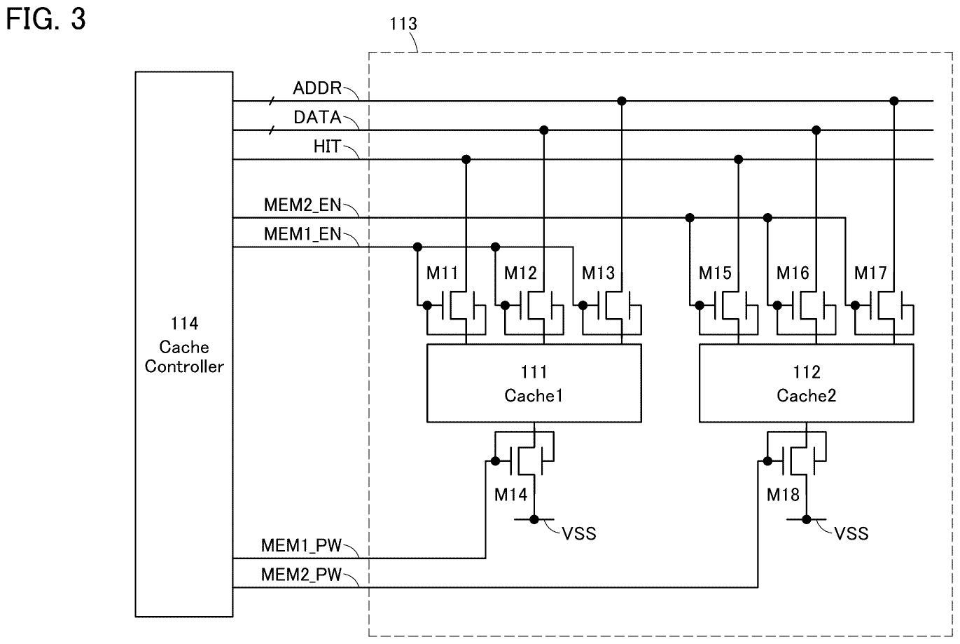

Note that a transistor functioning as a switch can be used as each of the switch SW11 to the switch SW18. FIG. 3 illustrates a structure in which the switch SW11, the switch SW12, the switch SW13, the switch SW14, the switch SW15, the switch SW16, the switch SW17, and the switch SW18 are replaced with a transistor M11, a transistor M12, a transistor M13, a transistor M14, a transistor M15, a transistor M16, a transistor M17, and a transistor M18, respectively.

Note that in FIG. 3, a structure in which the cache portion 113 includes one transistor M13 and one transistor M17 is illustrated for simple description; however, a plurality of transistors M13 and a plurality of transistors M17 are provided in accordance with the number of bits of the signal ADDR. In addition, a structure in which the cache portion 113 includes one transistor M12 and one transistor M16 is illustrated; however, a plurality of transistors M12 and a plurality of transistors M16 are provided in accordance with the number of bits of the signal DATA.

An OS transistor can be used as each of the transistor M11 to the transistor M18. With the use of the OS transistor as each of the transistor M11 to the transistor M18, the ratio between on-state current and off-state current can be large and a favorable switching operation can be performed even in a high-temperature environment. For example, in the first cache mode, the on-state current of the transistor M11 to the transistor M13 in the on state is high and the off-state current of the transistor M18 in the off state is low even in a high-temperature environment. For example, in the second cache mode, the on-state current of the transistor M15 to the transistor M17 in the on state is high and the off-state current of the transistor M14 in the off state is low even in a high-temperature environment. Consequently, the operating speed of the semiconductor device 100 can be improved. Furthermore, a reduction in the power consumption of the semiconductor device 100 can be achieved. A decrease in operating speed of the semiconductor device 100 due to a temperature increase can be inhibited.

### [Structure Example of Cache]

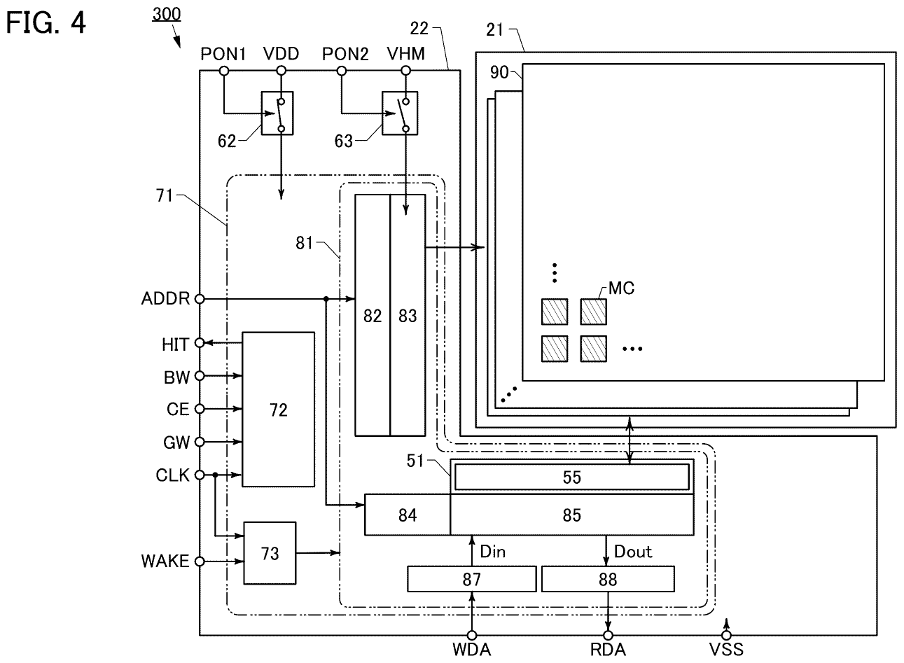

FIG. 4 is a block diagram illustrating a structure example of a memory device 300 that can be suitably used as the second cache 112 of one embodiment of the present invention.

As illustrated in FIG. 4, the memory device 300 includes a memory cell portion 21 and a driver circuit portion 22.

The memory cell portion 21 includes a plurality of memory cell arrays 90 that are provided to be stacked. The memory cell array 90 includes a plurality of memory cells MC arranged in a matrix. A structure example of the memory cell MC will be described later.

The driver circuit portion 22 includes a PSW 62 (power switch), a PSW 63, and a peripheral circuit 71. The peripheral circuit 71 includes a peripheral circuit 81, a control circuit 72, and a voltage generation circuit 73.

In the memory device 300, each circuit, each signal, and each voltage can be appropriately selected as needed. Alternatively, another circuit or another signal may be added. A signal BW, a signal CE, a signal GW, the signal CLK, a signal WAKE, the signal ADDR, a signal WDA, a signal PON1, and a signal PON2 are input signals from the outside. The signal HIT and a signal RDA are output signals to the outside.

The signal CLK is a clock signal. The signal BW, the signal CE, and the signal GW are control signals. The signal CE is a chip enable signal. The signal GW is a global write enable signal. The signal BW is a byte write enable signal. The signal ADDR is an address signal. The signal HIT is a signal indicating whether data corresponding to an address signal exists in the memory cell portion 21. The signal WDA is write data. The signal RDA is read data. The signal PON1 and the signal PON2 are power gating control signals. Note that the signal PON1 and the signal PON2 may be generated in the control circuit 72.

The control circuit 72 is a logic circuit having a function of controlling the entire operation of the memory device 300. For example, the control circuit 72 outputs, as the signal HIT, whether data corresponding to an address signal exists in the memory cell portion 21. For example, the control circuit 72 performs a logical operation on the signal CE, the signal GW, and the signal BW to determine an operation mode of the memory device 300 (e.g., a write operation or a read operation (e.g., a reading mode 1 or a reading mode 2)). Alternatively, the control circuit 72 generates a control signal for the peripheral circuit 81 so that the operation mode is executed.

The voltage generation circuit 73 has a function of generating a negative voltage. The signal WAKE has a function of controlling the input of the signal CLK to the voltage generation circuit 73. For example, in the voltage generation circuit 73, when an H-level signal is supplied as the signal WAKE, the signal CLK is input to the voltage generation circuit 73 and a negative voltage is generated.

The peripheral circuit 81 is a circuit for writing or reading data to and from the memory cells MC. The peripheral circuit 81 includes a row decoder 82, a column decoder 84, a row driver 83, a column driver 85, an input circuit 87, an output circuit 88, and a driver circuit 51 including a sense amplifier 55.

The row decoder 82 and the column decoder 84 have a function of decoding the signal ADDR. The row decoder 82 is a circuit for specifying a row to be accessed. The column decoder 84 is a circuit for specifying a column to be accessed. The row driver 83 has a function of selecting a word line specified by the row decoder 82. The column driver 85 has a function of selecting a bit line specified by the column decoder 84. The driver circuit 51 has a function of writing data, a function of reading data with the sense amplifier 55, or a function of retaining the read data, to and from the memory cells MC selected by the word line selected by the row driver 83 and the bit line selected by the column driver 85, for example.

The input circuit 87 has a function of retaining the signal WDA. Data retained by the input circuit 87 is output to the column driver 85. Data output from the input circuit 87 is data (data Din) to be written to the memory cells MC. Data (data Dout) read from the memory cells MC by the column driver 85 is output to the output circuit 88. The output circuit 88 has a function of retaining the data Dout. In addition, the output circuit 88 has a function of outputting the data Dout to the outside of the memory device 300. Data output from the output circuit 88 is the signal RDA.

The PSW 62 has a function of controlling supply of the potential VDD to the peripheral circuit 71. The PSW 63 has a function of controlling supply of a potential VHM to the row driver 83. Here, the potential of the memory device 300 on the high power supply side is the potential VDD, and the potential of the memory device 300 on the low power supply side is the potential VSS. The potential VHM is a potential used to set the word line to an H level (a potential for turning on a transistor electrically connected to the word line) and is higher than the potential VDD. The PSW 62 is controlled to be in an on state or an off state by the signal PON1. The PSW 63 is controlled to be in an on state or an off state by the signal PON2. The number of power domains to which the potential VDD is supplied is one in the peripheral circuit 71 in FIG. 4 but can be more than one. In that case, the driver circuit portion 22 is provided with a power switch for each power domain.

### [Structure Example of Memory Cell]

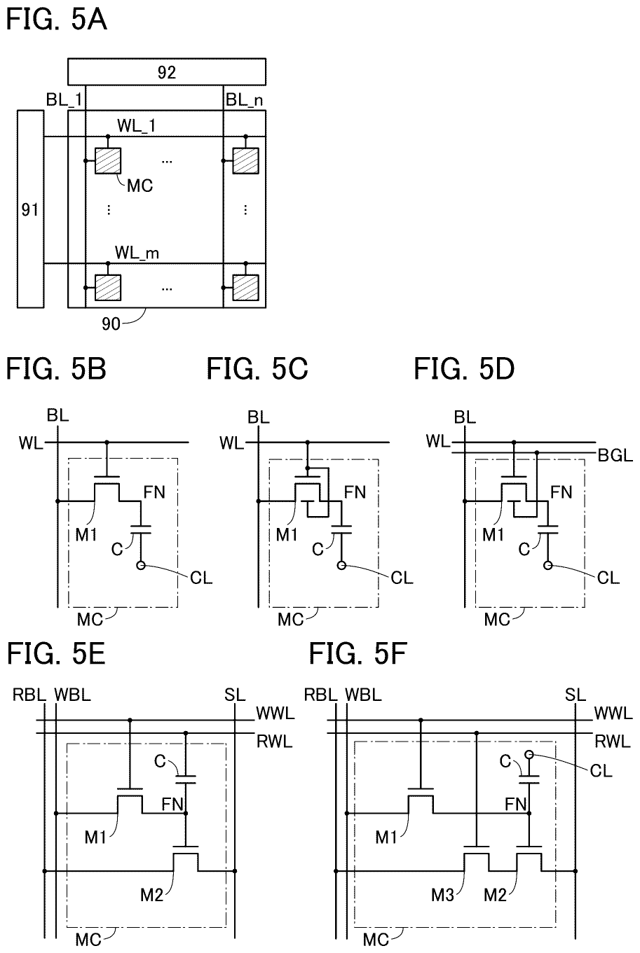

FIG. 5A is a block diagram illustrating a structure example of a memory circuit that can be suitably used for the memory device 300 of one embodiment of the present invention.

In the block diagram in FIG. 5A, the memory cell array 90, a word line driver circuit 91, and a bit line driver circuit 92 are illustrated.

The memory cell array 90 includes the memory cells MC arranged in a matrix of m rows and n columns (m and n are each a positive integer). The memory cells MC are electrically connected to a word line WL_1 to a word line WL_m and a bit line BL_1 to a bit line BL_n. The memory cells MC may be electrically connected to a source line for supplying current, a wiring for applying a potential to a back gate of a transistor, a capacitor line for setting one electrode of a capacitor to a fixed potential, or the like, in addition to the bit lines and the word lines.

The word line driver circuit 91 is a circuit that outputs a signal for selecting the memory cells MC in each row. The word line driver circuit 91 corresponds to, for example, the row decoder 82, the row driver 83, and the like included in the driver circuit portion 22 of the memory device 300. Word lines for data writing and word lines for data reading may be provided separately for the word line WL_1 to the word line WL_m. Note that in the description described later, one word line selected from the word line WL_1 to the word line WL_m is sometimes referred to as a word line WL.

The bit line driver circuit 92 is a circuit for writing data into the memory cell MC in each column, or for reading data from the memory cells MC. The bit line driver circuit 92 corresponds to, for example, the driver circuit 51 including the column decoder 84, the column driver 85, and the sense amplifier 55, which is included in the driver circuit portion 22 of the memory device 300. Bit lines for data writing and bit lines for data reading may be provided separately for the bit line BL_1 to the bit line BL_n. Note that in the description described later, one bit line selected from the bit line BL_1 to the bit line BL_n is sometimes referred to as a bit line BL.

FIG. 5B to FIG. 5F are diagrams each illustrating a circuit structure example that can be employed for the memory cell MC illustrated in FIG. 5A.

The memory cell MC illustrated in FIG. 5B includes a transistor M1 and a capacitor C. One of a source and a drain of the transistor M1 is electrically connected to one electrode of the capacitor C. The other of the source and the drain of the transistor M1 is electrically connected to the bit line BL. A gate of the transistor M1 is electrically connected to the word line WL. The other electrode of the capacitor C is electrically connected to a capacitor line CL. The transistor M1 is an OS transistor. The OS transistor has a feature of extremely low off-state current. Thus, bringing the transistor M1 into a non-conduction state allows a charge retention node FN to retain charge in accordance with data. Thus, the refresh rate of the data in accordance with charge retained in the charge retention node FN can be reduced.

The memory cell MC illustrated in FIG. 5C is a variation example of the memory cell MC illustrated in FIG. 5B. The memory cell MC in FIG. 5C is different from the transistor M1 in FIG. 5B in that the transistor M1 includes a back gate, and the back gate and the gate are electrically connected to each other so that a potential of the word line WL is applied from both the back gate and the gate. Adopting such a structure can increase the amount of current flowing between a source and a drain when the transistor M1 is turned on.

The memory cell MC illustrated in FIG. 5D is a variation example of the memory cell MC illustrated in FIG. 5B. The memory cell MC in FIG. 5D is different from the transistor M1 in FIG. 5B in that the transistor M1 includes a back gate, and the back gate and a back gate line BGL are electrically connected to each other so that a potential different from that of the gate is applied to the back gate. Such a structure enables control of threshold voltage of the transistor M1. Accordingly, the amount of current flowing between the source and the drain of the transistor M1 can be changed.

The memory cell MC illustrated in FIG. 5E includes the transistor M1, a transistor M2, and the capacitor C. One of the source and the drain of the transistor M1 is electrically connected to a gate of the transistor M2 and one electrode of the capacitor C. The other of the source and the drain of the transistor M1 is electrically connected to a write bit line WBL. The gate of the transistor M1 is electrically connected to a write word line WWL. The other electrode of the capacitor C is electrically connected to a read word line RWL. One of a source and a drain of the transistor M2 is electrically connected to a read bit line RBL. The other of the source and the drain of the transistor M2 is electrically connected to a source line SL. Although an n-channel transistor is illustrated as the transistor M2, a p-channel transistor may also be employed. Bringing the transistor M1 into a non-conduction state allows the charge retention node FN to retain charge in accordance with data. The transistor M2 is an OS transistor. Note that the transistor M2 may be a Si transistor. Note that the transistor M1 can have a structure similar to that of the transistor M1 illustrated in FIG. 5C or FIG. 5D.

The memory cell MC illustrated in FIG. 5F includes the transistor M1, the transistor M2, a transistor M3, and the capacitor C. One of the source and the drain of the transistor M1 is electrically connected to the gate of the transistor M2 and one electrode of the capacitor C. The other of the source and the drain of the transistor M1 is electrically connected to the write bit line WBL. The gate of the transistor M1 is electrically connected to the write word line WWL. The other electrode of the capacitor C is electrically connected to the capacitor line CL. One of the source and the drain of the transistor M2 is electrically connected to one of a source and a drain of the transistor M3. The other of the source and the drain of the transistor M2 is electrically connected to the source line SL. A gate of the transistor M3 is electrically connected to the read word line RWL. The other of the source and the drain of the transistor M3 is electrically connected to the read bit line RBL. Although an n-channel transistor is illustrated as the transistor M3, a p-channel transistor may also be employed. Bringing the transistor M1 into a non-conduction state allows the charge retention node FN to retain charge in accordance with data. The transistor M2 and the transistor M3 are each preferably an OS transistor. Note that at least one of the transistor M2 and the transistor M3 may be a Si transistor. Note that the transistor M1 can have a structure similar to that of the transistor M1 illustrated in FIG. 5C or FIG. 5D.

Note that the structures of the memory cells illustrated in FIG. 5B to FIG. 5D are each referred to as a DOSRAM (registered trademark). The DOSRAM is an abbreviation for a Dynamic Oxide Semiconductor RAM (Random Access Memory). In the structure using the DOSRAM, when one of a source and a drain of an OS transistor and one electrode of the capacitor are electrically connected to each other, charge accumulated in the one electrode of the capacitor can be retained when the OS transistor is brought into a non-conduction state. In particular, a structure using the DOSRAM is effective in the case where the stored data is increased. For example, as compared to a structure where memory cells in the memory circuit are formed with an SRAM (Static RAM), the structure using the DOSRAM can inhibit an increase in a circuit area. In particular, the structures of the memory cells illustrated in FIG. 5B to FIG. 5D are effective in inhibiting an increase in the circuit area.

The structures of the memory cells illustrated in FIG. 5E and FIG. 5F are each referred to as a NOSRAM (registered trademark). The NOSRAM is an abbreviation for a Nonvolatile Oxide Semiconductor RAM. In the structure using the NOSRAM, when one of a source and a drain of a writing OS transistor and a gate of a reading transistor are electrically connected to each other, charge accumulated in the gate of the reading transistor can be retained when the writing OS transistor is brought into a non-conduction state. The structure using the NOSRAM may be used as a nonvolatile memory. For example, when a writing OS transistor is brought into the non-conduction state, the NOSRAM can store data even in a power gating state.

Note that the circuit structures illustrated in FIG. 5B to FIG. 5F are merely examples, and any other structures can be employed as long as one embodiment of the present invention can be achieved.

### <Operation Example>

An operation example of the semiconductor device 100 of one embodiment of the present invention is described. The semiconductor device 100 operates in a normal state or an overheated state. In this embodiment and the like, the normal state is a state where a temperature T around or inside the core 115 is lower than a temperature threshold value Tth that is predetermined in advance (the temperature T is lower than the temperature threshold value Tth). The overheated state is a state where the temperature T around or inside the core 115 is higher than or equal to the temperature threshold value Tth that is predetermined in advance (the temperature T is higher than or equal to the temperature threshold value Tth). In the normal state, when a state where the temperature T is higher than or equal to the temperature threshold value Tth continues for a certain period of time, the normal state transfers to an overheated state. In the overheated state, when a state where the temperature T is lower than the temperature threshold value Tth continues for a certain period of time, the overheated state transfers to a normal state.

Note that as the temperature threshold value Tth, a temperature higher than or equal to 60° C. and lower than or equal to 100° C., preferably higher than or equal to 60° C. and lower than or equal to 80° C. is set, for example.

As the certain period of time, preferably, a time longer than or equal to 0.1 seconds and shorter than or equal to 10 seconds, further preferably a time longer than or equal to 0.1 seconds and shorter than or equal to 1 second is set.

In the case where the semiconductor device 100 is in the normal state, program processing is performed in the core 115 using the first cache 111. That is, in the case of the normal state, the cache portion 113 operates in the first cache mode (the first cache 111 is in an effective state and the second cache 112 is in an ineffective state). In the case where the semiconductor device 100 is in the overheated state, program processing is performed in the core 115 using the second cache 112. That is, in the case of the overheated state, the cache portion 113 operates in the second cache mode (the second cache 112 is in an effective state and the first cache 111 is in an ineffective state). Note that the semiconductor device 100 performs processing for switching the operation of the cache portion 113 from the first cache mode to the second cache mode when transitioning from the normal state to the overheated state. When transitioning from the overheated state to the normal state, the semiconductor device 100 performs processing for switching the operation of the cache portion 113 from the second cache mode to the first cache mode.

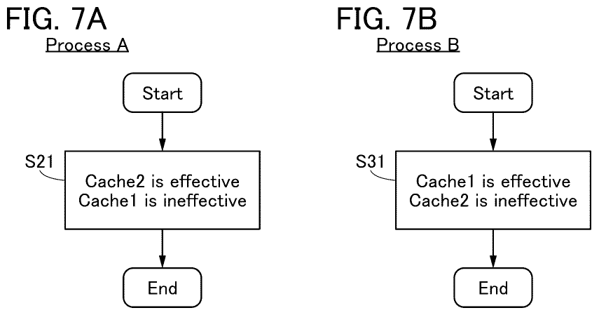

FIG. 6, FIG. 7A, and FIG. 7B are flowcharts each showing an operation example of the semiconductor device 100. The flowchart illustrated in FIG. 6 is an operation example of the semiconductor device 100 in each of a normal state (the first cache mode), transition from a normal state to an overheated state (switching from the first cache mode to the second cache mode), an overheated state (the second cache mode), and transition from an overheated state to a normal state (switching from the second cache mode to the first cache mode). The flowchart illustrated in FIG. 7A is an example of processing (Process A) for switching from the first cache mode to the second cache mode. The flowchart illustrated in FIG. 7B is an example of processing (Process B) for switching from the second cache mode to the first cache mode.

### [Normal State (First Cache Mode)]

While the program processing is executed (Step S01), an operation described below is performed. In the normal state, at least one core 115 included in the semiconductor device 100 executes program processing. First, the thermal detector 116 measures the temperature T around or inside the core 115 with the use of the temperature sensor 131 (Step S02). Then, the thermal detector 116 transmits information on whether the temperature T is higher than or equal to the predetermined temperature threshold value Tth (the temperature T is higher than or equal to the temperature threshold value Tth) to the cache controller 114 through the bus 117.

Next, the cache controller 114 receives the information on whether the temperature T is higher than or equal to the temperature threshold value Tth from the thermal detector 116, and determines whether the semiconductor device 100 is in the overheated state (whether the state where the temperature T is higher than or equal to the temperature threshold value Tth continues for a certain period of time) (Step S03). In the case of the normal state (not in the overheated state), the cache controller 114 determines whether the second cache 112 is in an effective state (Step S08). The normal state corresponds to the first cache mode (the second cache 112 is not in an effective state); thus, the processing returns to Step S01.

That is, the semiconductor device 100 repeats Step S01, Step S02, Step S03, and Step S08 in this order while the program processing is executed in the normal state.

### [Transition From Normal State to Overheated State (Switching From First Cache Mode to Second Cache Mode)]

When the program processing is continued in the normal state, the temperature T around or inside the core 115 increases to be higher than or equal to the predetermined temperature threshold value Tth (the temperature T is higher than or equal to the temperature threshold value Tth) in some cases. In the case where the state where the temperature T is higher than or equal to the temperature threshold value Tth continues for a certain period of time, it is determined that the state is the overheated state in Step S03. In the case of the overheated state, the cache controller 114 determines whether the first cache 111 is in an effective state (Step S04). Immediately after transitioning from the normal state to the overheated state, the state is the first cache mode (the first cache 111 is in an effective state); thus, switching from the first cache mode to the second cache mode is performed (Step S05 to Step S07). After switching from the first cache mode to the second cache mode is performed, the processing returns to Step S01.

Switching from the first cache mode to the second cache mode is described. First, the cache controller 114 transmits an interrupt request to the core 115, and the core 115 that receives the request stops executing program processing (Step S05). Next, the cache controller 114 performs Process A (processing for switching from the first cache mode to the second cache mode) (Step S06). For example, the cache controller 114 is controlled so as to communicate with the second cache 112 when the read request is received from the core 115. Then, the cache controller 114 transmits an interrupt request to the core 115, and the core 115 that receives the request restarts the suspended program processing (Step S07).

Process A in Step S06 is described (see FIG. 7A). In Process A, the cache controller 114 brings the first cache 111 into an ineffective state and brings the second cache 112 into an effective state (Step S21).

Specifically, for example, in FIG. 2, the cache controller 114 outputs the signal MEM1_EN with which the switch SW11 to the switch SW13 are turned off, the signal MEM2_EN with which the switch SW15 to the switch SW17 are turned on, and the signal MEM2_PW with which the switch SW18 is turned on. For example, in FIG. 3, the cache controller 114 outputs the signal MEM1_EN at an L level, the signal MEM2_EN at an H level, and the signal MEM2_PW at an H level. Here, the L level is a potential at which the transistor M11 to the transistor M13 are turned off (e.g., the potential VSS or a potential lower than the potential VSS). The H level is a potential at which the transistor M15 to the transistor M18 are turned on (e.g., the potential VDD or a potential higher than the potential VDD).

Accordingly, the cache controller 114 transmits and receives the signal ADDR, the signal DATA, and the signal HIT to and from the second cache 112 when receiving the read request from the core 115.

Furthermore, the first cache 111 is not involved in the signal ADDR, the signal DATA, and the signal HIT. In other words, the first cache 111 is not used to execute the program processing. Thus, for example, the cache controller 114 may stop power supply to the first cache 111. When power supply to the first cache 111 is stopped, the power consumption of the semiconductor device 100 can be reduced.

As an example of a method for stopping the power supply to the first cache 111, in FIG. 2, the cache controller 114 may output the signal MEM1_PW with which the switch SW14 is turned off. For example, in FIG. 3, the cache controller 114 may output the signal MEM1_PW at an L level. Here, the L level is a potential at which the transistor M14 is turned off (e.g., the potential VSS or a potential lower than the potential VSS).

Alternatively, as another example of a method for stopping the power supply to the first cache 111, the cache controller 114 may transmit a command for stopping the power supply to the first cache 111 to the power controller 122, and the power controller 122 may receive the command to stop the power supply to the first cache 111.

For example, the cache controller 114 may stop supply of a clock signal to the first cache 111. The supply of the clock signal to the first cache 111 is stopped, whereby power consumption of the semiconductor device 100 can be reduced.

As an example of a method for stopping supply of the clock signal to the first cache 111, the cache controller 114 may transmit a command for stopping supply of the clock signal to the first cache 111 to the clock controller 123, and the clock controller 123 may receive the command to stop supply of the clock signal to the first cache 111.

### [Overheated State (Second Cache Mode)]

After transitioning to the overheated state and the switching to the second cache mode is performed, it is determined that Step S03 is in the overheated state while the overheated state continues. Then, in Step S04, it is determined that the state is the second cache mode (the first cache 111 is not in an effective state).

That is, the semiconductor device 100 repeats Step S01, Step S02, Step S03, and Step S04 in this order while the program processing is executed in the overheated state.

### [Transition From Overheated State to Normal State (Switching From Second Cache Mode to First Cache Mode)]

When the program processing continues in the overheated state, the temperature T around or inside the core 115 decreases to be lower than the predetermined temperature threshold value Tth (the temperature T is lower than the temperature threshold value Tth) in some cases. In the case where the state where the temperature T is lower than the temperature threshold value Tth continues for a certain period of time, it is determined that the state is the normal state (not in the overheated state) in Step S03. In the normal state, the cache controller 114 determines whether the second cache 112 is in an effective state (Step S08). Immediately after transitioning from the overheated state to the normal state, the state is the second cache mode (the second cache 112 is in an effective state); thus, switching from the second cache mode to the first cache mode is performed (Step S09 to Step S11). After switching from the second cache mode to the first cache mode is performed, the processing returns to Step S01.

Switching from the second cache mode to the first cache mode is described. First, the cache controller 114 transmits an interrupt request to the core 115, and the core 115 that receives the request stops executing program processing (Step S09). Next, the cache controller 114 performs Process B (the processing for switching from the second cache mode to the first cache mode) (Step S10). For example, the cache controller 114 may be controlled so as to communicate with the first cache 111 when the read request is received from the core 115. Then, the cache controller 114 transmits an interrupt request to the core 115, and the core 115 that receives the request restarts the suspended program processing (Step S11).

Process B in Step S10 is described (see FIG. 7B). In Process B, the cache controller 114 brings the second cache 112 into an ineffective state and brings the first cache 111 into an effective state (Step S31).

Specifically, for example, in FIG. 2, the cache controller 114 outputs the signal MEM1_EN with which the switch SW11 to the switch SW13 are turned on, the signal MEM1_PW with which the switch SW14 is turned on, and the signal MEM2_EN with which the switch SW15 to the switch SW17 are turned off. For example, in FIG. 3, the cache controller 114 outputs the signal MEM1_EN at an H level, the signal MEM1_PW at an H level, and the signal MEM2_EN at an L level. Here, the H level is a potential at which the transistor M11 to the transistor M14 are turned on (e.g., the potential VDD or a potential higher than the potential VDD). The L level is a potential at which the transistor M15 to the transistor M17 are turned on (e.g., the potential VSS or a potential lower than the potential VSS).

Accordingly, the cache controller 114 transmits and receives the signal ADDR, the signal DATA, and the signal HIT to and from the first cache 111 when receiving the read request from the core 115.

Furthermore, the second cache 112 is not involved in the signal ADDR, the signal DATA, and the signal HIT. In other words, the second cache 112 is not used to execute the program processing. Thus, for example, the cache controller 114 may stop power supply to the second cache 112. When power supply to the second cache 112 is stopped, the power consumption of the semiconductor device 100 can be reduced.

As an example of a method for stopping the power supply to the second cache 112, in FIG. 2, the cache controller 114 may output the signal MEM2_PW with which the switch SW18 is turned off. For example, in FIG. 3, the cache controller 114 may output the signal MEM2_PW at an L level. Here, the L level is a potential at which the transistor M18 is turned off (e.g., the potential VSS or a potential lower than the potential VSS).

Alternatively, as another example of a method for stopping the power supply to the second cache 112, the cache controller 114 may transmit a command for stopping the power supply to the second cache 112 to the power controller 122, and the power controller 122 may receive the command to stop the power supply to the second cache 112.

For example, the cache controller 114 may stop supply of a clock signal to the second cache 112. The supply of the clock signal to the second cache 112 is stopped, whereby power consumption of the semiconductor device 100 can be reduced.

As an example of a method for stopping supply of the clock signal to the second cache 112, the cache controller 114 may transmit a command for stopping supply of the clock signal to the second cache 112 to the clock controller 123, and the clock controller 123 may receive the command to stop supply of the clock signal to the second cache 112.

As described above, the first cache 111 and the second cache 112 are switched to be used in accordance with the temperature around or inside the core 115, a decrease in operating speed due to an increase in temperature of the semiconductor device 100 can be inhibited.

### <Operation Example 2>

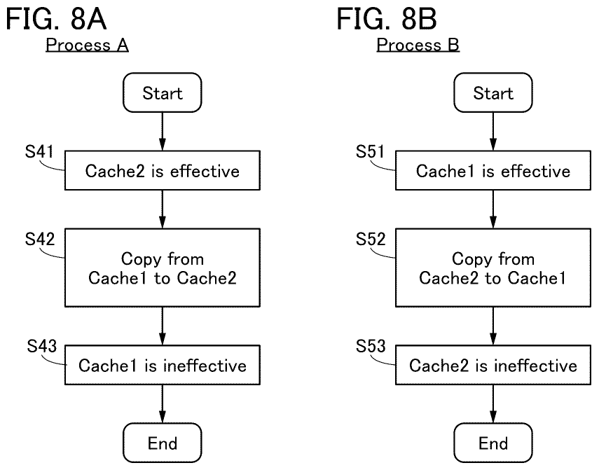

The operation of the semiconductor device 100 of one embodiment of the present invention is not limited to the above-described operation example. For example, in the flowchart shown in FIG. 6, Process A (the processing for switching from the first cache mode to the second cache mode) is not limited to the flowchart shown in FIG. 7A. FIG. 8A is a flowchart showing another example of Process A. In the flowchart shown in FIG. 6, Process B (the processing for switching from the second cache mode to the first cache mode) is not limited to the flowchart shown in FIG. 7B. FIG. 8B is a flowchart showing another example of Process B.

Note that in the description of FIG. 8A and FIG. 8B described later, the above description can be referred to as appropriate for portions similar to those in FIG. 7A and FIG. 7B; thus, the description is omitted in some cases.

In Process A shown in FIG. 8A, first, the second cache 112 is brought into an effective state (Step S41). Next, information (e.g., data, address, and attribute information) stored in the first cache 111 is copied to the second cache 112 (Step S42). Then, the first cache 111 is brought into an ineffective state (Step S43).

Specifically, in Step S41, the cache controller 114 outputs the signal MEM2_EN with which the switch SW15 to the switch SW17 are turned on and the signal MEM2_PW with which the switch SW18 is turned on, in FIG. 2, for example. Accordingly, the cache controller 114 can transmit and receive the signal ADDR, the signal DATA, and the signal HIT to and from the second cache.

Next, in Step S42, for example, the cache controller 114 is controlled so as to read information (e.g., data, address, and attribute information) stored in the first cache 111 from the first cache 111 through the signal ADDR, the signal DATA, and the signal HIT and to write the read information to the second cache 112.

Then, in Step S43, the cache controller 114 outputs the signal MEM1_EN with which the switch SW11 to the switch SW13 are turned off, in FIG. 2, for example. Thus, the first cache 111 is not involved in the signal ADDR, the signal DATA, and the signal HIT. Note that the cache controller 114 may output a signal EM1_PW with which the switch SW14 is turned off. Thus, power supply to the first cache 111 is stopped, whereby power consumption of the semiconductor device 100 can be reduced.

Thus, in the case where Process A shown in FIG. 8A is employed, information (e.g., data, address, and attribute information) stored in the first cache 111 at the time when the program processing is stopped in Step S05 is copied to the second cache 112 in Step S06. That is, when the program processing is restarted in Step S07, data for performing the program processing in the core 115 is stored in the second cache 112. Thus, when the cache controller 114 receives the read request from the core 115 after the program processing is restarted, the data can be transmitted to and received from the second cache 112 without being read from the memory 141. Consequently, the operating speed of the semiconductor device 100 can be improved.

In Process B illustrated in FIG. 8B, first, the first cache 111 is brought into an effective state (Step S51). Next, information (e.g., data, address, and attribute information) stored in the second cache 112 is copied to the first cache 111 (Step S52). Then, the second cache 112 is brought into an ineffective state (Step S53).

Specifically, in Step S51, the cache controller 114 outputs the signal MEM1_EN with which the switch SW11 to the switch SW13 are turned on and the signal MEM1-PW with which the switch SW14 is turned on, in FIG. 2, for example. Accordingly, the cache controller 114 can transmit and receive the signal ADDR, the signal DATA, and the signal HIT to and from the first cache.

Next, in Step S52, for example, the cache controller 114 is controlled so as to read information (e.g., data, address, and attribute information) stored in the second cache 112 from the second cache 112 through the signal ADDR, the signal DATA, and the signal HIT and to write the read information to the first cache 111.

Then, in Step S53, the cache controller 114 outputs the signal MEM2_EN with which the switch SW15 to the switch SW17 are turned off, in FIG. 2, for example. Thus, the second cache 112 is not involved in the signal ADDR, the signal DATA, and the signal HIT. Note that the cache controller 114 may output a signal EM2_PW with which the switch SW18 is turned off. Thus, power supply to the second cache 112 is stopped, whereby power consumption of the semiconductor device 100 can be reduced.

Thus, in the case where Process B shown in FIG. 8B is employed, information (e.g., data, address, and attribute information) stored in the second cache 112 at the time when the program processing is stopped in Step S09 is copied to the first cache 111 in Step S10. That is, when the program processing is restarted in Step S11, data for performing the program processing in the core 115 is stored in the first cache 111. Thus, when the cache controller 114 receives the read request from the core 115 after the program processing is restarted, the data can be transmitted to and received from the first cache 111 without being read from the memory 141. Consequently, the operating speed of the semiconductor device 100 can be improved.

The semiconductor device of one embodiment of the present invention is not limited to the description of the semiconductor device 100 described above. At least part of the structure examples, the operation examples, the drawings corresponding thereto, and the like described in this embodiment as an example can be combined with the other structure examples, the other operation examples, the other drawings, and the other embodiments described in this specification and the like as appropriate.

### Embodiment 2

In this embodiment, mounting examples of the above-described semiconductor device will be described.

### <Mounting Example>

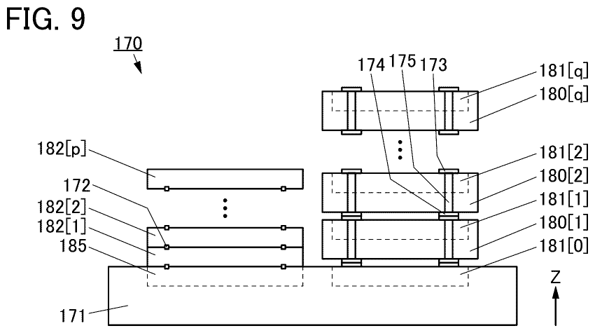

FIG. 9 is a schematic diagram illustrating a mounting example of a semiconductor device 170 of one embodiment of the present invention. As illustrated in FIG. 9, the semiconductor device 170 includes a substrate 171. The substrate 171 is, for example, a substrate containing silicon. Note that as the substrate 171, a substrate containing a compound semiconductor such as silicon carbide or gallium nitride may be used, for example.

Note that in the schematic diagram illustrated in FIG. 9, the Z direction is defined for easy understanding of the description of the positional relationship between components that constitute the semiconductor device 170. In FIG. 9, the Z direction is a direction perpendicular or substantially perpendicular to a surface of the substrate 171. In this embodiment and the like, “substantially perpendicular” indicates a state where the angle formed between two elements to be subjected is greater than or equal to 85° and less than or equal to 95°. In this embodiment and the like, the Z direction is sometimes referred to as a perpendicular direction for easy understanding.

A core region 185 and a memory region 181[0] are formed on one surface side of the substrate 171. Each of the core region 185 and the memory region 181[0] is a region where a Si transistor (a transistor including silicon in a channel formation region) or a circuit including the Si transistors is provided.

One or more memory layers (a memory layer 182[1] to a memory layer 182[p] (p is a positive integer)) are formed to be stacked in the perpendicular direction over the core region 185. Each of the memory layer 182[1] to the memory layer 182[p] is a layer where an OS transistor (a transistor including an oxide semiconductor in a channel formation region) or a circuit including the OS transistors is provided.

A via hole 172 is formed between the substrate 171 and the memory layer 182[1] and between the memory layer 182[1] to the memory layer 182[p].

Between the substrate 171 and the memory layer 182[1] and between the memory layer 182[1] to the memory layer 182[p] are electrically connected to each other through the via holes 172 formed therebetween. That is, a circuit provided on one surface side of the substrate 171 and a circuit provided in each of the memory layer 182[1] to the memory layer 182[p] are electrically connected to each other through the via holes 172 formed therebetween. For example, through the via hole 172 formed between the substrate 171 and the memory layer 182[1], the circuit provided on one surface side of the substrate 171 and the circuit provided in the memory layer 182[1] are electrically connected to each other. Through the via hole 172 formed between the memory layer 182[1] and the memory layer 182[2], the circuit provided in the memory layer 182[1] and the circuit provided in the memory layer 182[2] are electrically connected to each other.

That is, the substrate 171 and the memory layer 182[1] to the memory layer 182[p] are monolithically formed.

One or more dies (a die 180[1] to a die 180[q] (q is a positive integer)) are provided to be stacked in the perpendicular direction over the memory region 181[0]. Each of the die 180[1] to the die 180[q] is a silicon die, for example.

Note that in this specification and the like, a die refers to a chip obtained by, for example, forming a circuit pattern on a disc-like substrate (also referred to as a wafer) or the like and cutting the substrate with the pattern into dices in a manufacturing process of a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Each of the memory region 181[1] to the memory region 181[q] is formed on one surface side of each of the die 180[1] to the die 180[q] in a one-to-one correspondence. Each of the memory region 181[1] to the memory region 181[q] is a region where a Si transistor or a circuit including the Si transistors is provided.

An electrode 173 is formed on one surface side of each of the substrate 171 and the die 180[1] to the die 180[q] (i.e., over each of the memory region 181[0] to the memory region 181[q]). An electrode 174 is formed on the other surface side of each of the die 180[1] to the die 180[q]. In each of the die 180[1] to the die 180[q], a plug 175 electrically connecting the electrode 173 and the electrode 174 is formed to penetrate the die. The plug 175 is a through silicon via (TSV), for example.

The substrate 171 and each of the die 180[1] to the die 180[q] are electrically connected to each other by bonding the electrode 173 formed on one surface side of each of the substrate 171 and the die 180[1] to the die 180[q-1] and the electrode 174 formed on the other surface side of each of the die 180[1] to the die 180[q]. That is, the circuits provided in the memory region 181[0] to the memory region 181[q] are electrically connected to each other by bonding the electrode 173 formed on one surface side of each of the substrate 171 and the die 180[1] to the die 180[q-1] and the electrode 174 formed on the other surface side of each of the die 180[1] to the die 180[q]. For example, the electrode 173 formed on one surface side of the substrate 171 and the electrode 174 formed on the other surface side of the die 180[1] are bonded to each other, whereby the circuit provided in the memory region 181[0] and the circuit provided in the memory region 181[1] are electrically connected to each other. When the electrode 173 formed on one surface side of the die 180[1] is bonded to the electrode 174 formed on the other surface side of the die 180[2], the circuit provided in the memory region 181[1] and the circuit provided in the memory region 181[2] are electrically connected to each other.

Note that for each of the electrode 173 and the electrode 174, the same conductive material is preferably used. As the conductive material used for the electrode 173 and the electrode 174, for example, a metal film containing an element selected from aluminum, chromium, copper, tantalum, tin, zinc, gold, silver, platinum, titanium, molybdenum, or tungsten; a metal nitride film containing any of the above elements as its component (e.g., a titanium nitride film, a molybdenum nitride film, or a tungsten nitride film); or the like can be used. Copper is particularly preferably used as the conductive material for the electrode 173 and the electrode 174. In that case, it is possible to employ Cu—Cu direct bonding technique (a technique for establishing electrical continuity by connecting copper (Cu) electrodes to each other). Note that a micro-bump bonding technique in which micro-bumps are formed and bonded onto the electrode 173 and the electrode 174 may be employed.

Note that the electrode 173 is not necessarily formed on the die 180[q] in some cases, for example.

Alternatively, for example, each of the memory region 181[1] to the memory region 181[q] may be formed on the other surface side of each of the die 180[1] to the die 180[q] in a one-to-one correspondence. In that case, for example, the electrode 173 and the plug 175 are not necessarily formed in the die 180[q] in some cases.

For example, in FIG. 9, one surface side and the other surface side of the substrate 171 and each of the die 180[1] to the die 180[q] are provided to face each other; however, one embodiment of the present invention is not limited thereto. For example, one surface sides or the other surface sides of at least one of the die 180[1] to the die 180[q] may be provided to face each other. In this case, for example, the electrodes 173 or the electrodes 174 are bonded to each other, so that the die 180[1] to the die 180[q] are electrically connected to each other. For another example, the electrode 174 and the plug 175 are not necessarily formed in the die 180[q] in some cases.

Note that the semiconductor device 170 described in this embodiment is a mounting example of the semiconductor device 100 described in Embodiment 1. Thus, for example, the semiconductor device 170 can have a structure in which part of the first cache 111 included in the semiconductor device 100 (e.g., the memory cell portion) is provided in the memory region 181[0] to the memory region 181[q], part of the second cache 112 included in the semiconductor device 100 (e.g., the memory cell portion) is provided in the memory layer 182[1] to the memory layer 182[p], and the core 115 included in the semiconductor device 100 is provided in the core region 185. Note that other components included in the semiconductor device 100 (e.g., the cache controller 114 and the thermal detector 116) are preferably provided over the substrate 171, for example.

That is, the semiconductor device 170 has a structure in which the second cache 112 is provided to be stacked in the perpendicular direction over the core 115 provided on the substrate 171, for example. Accordingly, the second cache 112 can have a high memory density and a short signal delay time, for example. The semiconductor device 170 has a structure in which the first cache 111 is provided in the die 180[1] to the die 180[q] provided to be stacked in the perpendicular direction over the substrate 171, for example. Thus, the first cache 111 can have a high memory density and a short signal delay time, for example. Owing to these features, for example, the semiconductor device 170 can have a high operating speed and be reduced in size.

### <Mounting Example 2>

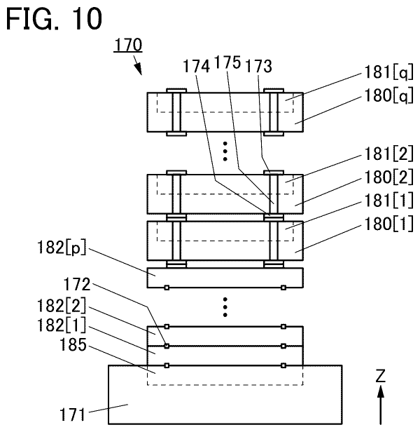

The mounting of the semiconductor device 170 of one embodiment of the present invention is not limited to the above-described mounting example. FIG. 10 is a schematic diagram illustrating another mounting example of the semiconductor device 170.

Note that in the following description of FIG. 10, the above description can be referred to as appropriate for portions similar to those in FIG. 9; thus, the description is omitted in some cases.

In the semiconductor device 170 illustrated in FIG. 10, the memory layer 182[1] to the memory layer 182[p] are formed to be stacked in the perpendicular direction over the core region 185 formed over the substrate 171. In addition, the die 180[1] to the die 180[q] in which the memory region 181[1] to the memory region 181[q] are formed, respectively, are provided to be stacked in the perpendicular direction over the memory layer 182[p].

The memory layer 182[p] and the die 180[1] are electrically connected to each other when the electrode 173 formed in the memory layer 182[p] and the electrode 174 formed on the other surface side of the die 180[1] are bonded to each other. That is, the circuit provided in the memory layer 182[p] and the circuit provided in the memory region 181[1] are electrically connected to each other when the electrode 173 formed on the memory layer 182[p] and the electrode 174 formed on the other surface side of the die 180[1] are bonded to each other.

That is, the semiconductor device 170 illustrated in FIG. 10 has a structure in which the second cache 112 is provided to be stacked in the perpendicular direction that is over the core 115 provided over the substrate 171 and the first cache 111 is provided to be stacked in the perpendicular direction that is over the second cache 112, for example. Thus, the first cache 111 can have a high memory density and a short signal delay time, for example. Owing to these features, for example, the operating speed of the semiconductor device 170 can be improved and be reduced in size.

Note that the memory layer 182[1] to the memory layer 182[p] provided with the second cache 112 can have a function of reducing the influence of heat generated in the core 115 on the first cache 111.

Note that the semiconductor device of one embodiment of the present invention is not limited to the semiconductor devices described above. At least part of the structure examples, the operation examples, the drawings corresponding thereto, and the like described in this embodiment as an example can be combined with the other structure examples, the other operation examples, the other drawings, and the other embodiments described in this specification and the like as appropriate.

### Embodiment 3

In this embodiment, structures of transistors that can be used in the semiconductor device described in the above embodiments will be described. For example, a structure in which transistors having different electrical characteristics are provided to be stacked will be described. With the structure, the flexibility in design of the semiconductor device can be increased. When transistors having different electrical characteristics are provided to be stacked, the integration degree of the semiconductor device can be increased.

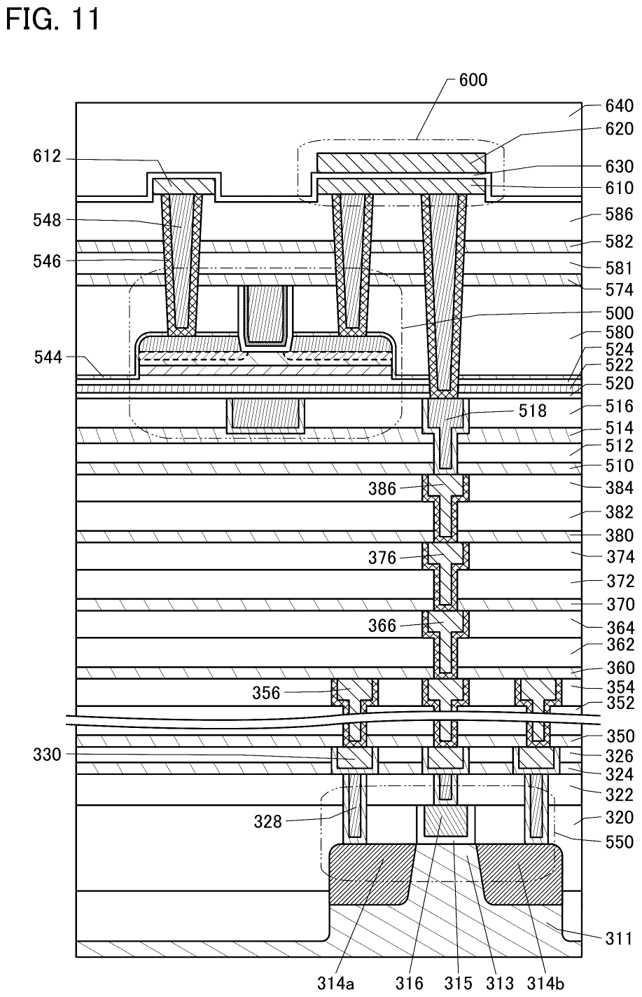

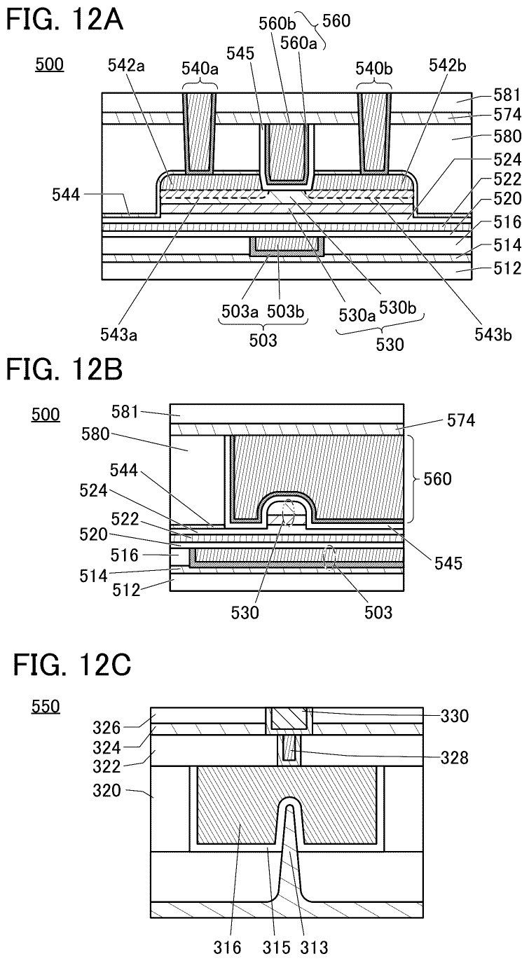

FIG. 11 illustrates part of a cross-sectional structure of a semiconductor device. The semiconductor device illustrated in FIG. 11 includes a transistor 550, a transistor 500, and a capacitor 600. FIG. 12A is a cross-sectional view of the transistor 500 in the channel length direction, FIG. 12B is a cross-sectional view of the transistor 500 in the channel width direction, and FIG. 12C is a cross-sectional view of the transistor 550 in the channel width direction. For example, the transistor 500 corresponds to the OS transistor described in the above embodiment and the transistor 550 corresponds to the Si transistor.

In FIG. 11, the transistor 500 is provided above the transistor 550, and the capacitor 600 is provided above the transistor 550 and the transistor 500.

The transistor 550 is provided in and on a substrate 311 and includes a conductor 316, an insulator 315, a semiconductor region 313 that is part of the substrate 311, and a low-resistance region 314a and a low-resistance region 314b functioning as a source region and a drain region.

As illustrated in FIG. 12C, the top surface and a side surface in the channel width direction of the semiconductor region 313 of the transistor 550 are covered with the conductor 316 with the insulator 315 therebetween. Such a Fin-type transistor 550 can have an increased effective channel width and thus have improved on-state characteristics of the transistor 550. In addition, contribution of the electric field of the gate electrode can be increased, so that the off-state characteristics of the transistor 550 can be improved.

Note that the transistor 550 may be either a p-channel transistor or an n-channel transistor.

The transistor 550 preferably contains a semiconductor such as a silicon-based semiconductor, further preferably contains single crystal silicon in a region of the semiconductor region 313 where a channel is formed, a region in the vicinity thereof, the low-resistance region 314a functioning as one of the source region and the drain region, the low-resistance region 314b functioning as the other of the source region and the drain region, and the like. Alternatively, the transistor 550 may be formed with a material containing Ge (germanium), SiGe (silicon germanium), GaAs (gallium arsenide), GaAlAs (gallium aluminum arsenide), or the like. For the transistor 550, a structure may be employed in which silicon whose effective mass is controlled by applying stress to the crystal lattice and thereby changing the lattice spacing. Alternatively, the transistor 550 may be an HEMT (High Electron Mobility Transistor) using GaAs and GaAlAs or the like, for example.

The low-resistance region 314a and the low-resistance region 314b contain an element that imparts n-type conductivity, such as arsenic or phosphorus, or an element that imparts p-type conductivity, such as boron, in addition to a semiconductor material used for the semiconductor region 313.

The conductor 316 functioning as a gate electrode can be formed using a semiconductor material such as silicon containing the element that imparts n-type conductivity, such as arsenic or phosphorus, or the element that imparts p-type conductivity, such as boron. Alternatively, a conductive material such as a metal material, an alloy material, or a metal oxide material can be used, for example.

Note that a material used for a conductor determines the work function; thus, selecting the material of the conductor can adjust the threshold voltage of a transistor. Specifically, a material such as titanium nitride or tantalum nitride is preferably used for the conductor, for example. Furthermore, in order to ensure both conductivity and embeddability, it is preferable to use stacked layers of metal materials such as tungsten and aluminum for the conductor, for example, and it is particularly preferable to use tungsten in terms of heat resistance. The transistor 550 may be formed using a SOI (Silicon on Insulator) substrate or the like, for example.

As the SOI substrate, any of the following substrates may be used: a SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature heating. Alternatively, an SOI substrate formed by a Smart-Cut method in which a semiconductor substrate is cleaved by utilizing growth of a minute void, which is formed by implantation of a hydrogen ion, by heat treatment or an ELTRAN method (registered trademark: Epitaxial Layer Transfer) may be used, for example. Note that a transistor formed using a single crystal substrate contains a single crystal semiconductor in a channel formation region.

An insulator 320, an insulator 322, an insulator 324, and an insulator 326 are provided to be stacked sequentially to cover the transistor 550.

The insulator 320, the insulator 322, the insulator 324, and the insulator 326 are formed using, for example, silicon oxide, silicon oxynitride, silicon nitride oxide, silicon nitride, aluminum oxide, aluminum oxynitride, aluminum nitride oxide, or aluminum nitride.

Note that in this specification and the like, silicon oxynitride refers to a material that has a higher oxygen content than a nitrogen content, and silicon nitride oxide refers to a material that has a higher nitrogen content than an oxygen content. Moreover, in this specification and the like, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by, for example, the transistor 550 or the like underlying the insulator 322. For example, the top surface of the insulator 322 may be planarized by planarization treatment using a chemical mechanical polishing (CMP) method or the like to increase the level of planarity.

For example, the insulator 324 is preferably formed using a film having a barrier property that prevents hydrogen, impurities, or the like from diffusing from the substrate 311, the transistor 550, or the like into a region where the transistor 500 is provided.

For the film having a barrier property against hydrogen, for example, silicon nitride deposited by a CVD method can be used. For example, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. Specifically, the film that inhibits hydrogen diffusion is a film from which a small amount of hydrogen is released.

The amount of released hydrogen can be measured by thermal desorption spectroscopy (TDS), for example. The amount of hydrogen released from the insulator 324 that is converted into hydrogen atoms per unit area of the insulator 324 is less than or equal to 1×10¹⁶ atoms/cm², preferably less than or equal to 5×10¹⁵ atoms/cm² in TDS analysis in a film-surface temperature range of 50° C. to 500° C., for example.

Note that the dielectric constant of the insulator 326 is preferably lower than that of the insulator 324. For example, the relative dielectric constant of the insulator 326 is preferably lower than 4, further preferably lower than 3. For example, the relative dielectric constant of the insulator 326 is preferably less than or equal to 0.7 times that of the insulator 324, further preferably less than or equal to 0.6 times that of the insulator 324. In the case where a material with a low dielectric constant is used for an interlayer film, the parasitic capacitance generated between wirings can be reduced.

A conductor 328, a conductor 330, and the like that are connected to the capacitor 600 or the transistor 500 are embedded in the insulator 320, the insulator 322, the insulator 324, and the insulator 326, for example. Note that the conductor 328 and the conductor 330 each have a function of a plug or a wiring. A plurality of conductors functioning as plugs or wirings are collectively denoted by the same reference numeral in some cases. In this specification and the like, a wiring and a plug electrically connected to the wiring may be a single component. That is, part of a conductor functions as a wiring and part of a conductor functions as a plug in other cases.

As a material for each of the plugs and wirings (e.g., the conductor 328 and the conductor 330), a conductive material such as a metal material, an alloy material, a metal nitride material, or a metal oxide material can be used in a single-layer structure or a stacked-layer structure. As the material for each of the plugs and the wirings, a high-melting point material that has both heat resistance and conductivity, such as tungsten or molybdenum, is preferably used, for example. Alternatively, as the material for each of the plugs and the wirings, a low-resistance conductive material such as aluminum or copper is preferably used. The use of a low-resistance conductive material for each of the plugs and the wirings can reduce wiring resistance.

A wiring layer may be provided over the insulator 326 and the conductor 330. For example, an insulator 350, an insulator 352, and an insulator 354 are stacked sequentially in FIG. 11. Furthermore, a conductor 356 is formed in the insulator 350, the insulator 352, and the insulator 354. The conductor 356 has a function of a plug or a wiring that is connected to the transistor 550. Note that the conductor 356 can be formed using a material similar to that for the conductor 328 and the conductor 330.

Note that for example, the insulator 350 is preferably formed using an insulator having a barrier property against hydrogen, like the insulator 324. Furthermore, the conductor 356 preferably includes a conductor having a barrier property against hydrogen. The conductor having a barrier property against hydrogen is formed particularly in an opening portion of the insulator 350 having a barrier property against hydrogen. In such a structure, the transistor 550 and the transistor 500 can be separated by a barrier layer. Thus, the hydrogen diffusion from the transistor 550 into the transistor 500 can be inhibited.

For the conductor having a barrier property against hydrogen, tantalum nitride or the like is preferably used, for example. Tantalum nitride and tungsten, which has high conductivity, is preferably stacked. When the conductor 356 is a stack of tantalum nitride and tungsten, the conductor 356 can inhibit hydrogen diffusion from the transistor 550 while the conductivity as a wiring is ensured. In that case, the tantalum nitride layer of the conductor 356 having a barrier property against hydrogen is preferably in contact with the insulator 350 having a barrier property against hydrogen.

A wiring layer may be provided over the insulator 354 and the conductor 356. For example, an insulator 360, an insulator 362, and an insulator 364 are stacked sequentially in FIG. 11. Furthermore, a conductor 366 is formed in the insulator 360, the insulator 362, and the insulator 364. The conductor 366 has a function of a plug or a wiring. Note that the conductor 366 can be formed using a material similar to that for the conductor 328 and the conductor 330.

Note that for example, the insulator 360 is preferably formed using an insulator having a barrier property against hydrogen, like the insulator 324. Furthermore, the conductor 366 preferably includes a conductor having a barrier property against hydrogen. The conductor having a barrier property against hydrogen is formed particularly in an opening portion of the insulator 360 having a barrier property against hydrogen. In such a structure, the transistor 550 and the transistor 500 can be separated by a barrier layer. Thus, the hydrogen diffusion from the transistor 550 into the transistor 500 can be inhibited.

A wiring layer may be provided over the insulator 364 and the conductor 366. For example, an insulator 370, an insulator 372, and an insulator 374 are stacked sequentially in FIG. 11. Furthermore, a conductor 376 is formed in the insulator 370, the insulator 372, and the insulator 374. The conductor 376 has a function of a plug or a wiring. Note that the conductor 376 can be formed using a material similar to that for the conductor 328 and the conductor 330.

Note that for example, the insulator 370 is preferably formed using an insulator having a barrier property against hydrogen, like the insulator 324. Furthermore, the conductor 376 preferably includes a conductor having a barrier property against hydrogen. The conductor having a barrier property against hydrogen is formed particularly in an opening portion of the insulator 370 having a barrier property against hydrogen. In such a structure, the transistor 550 and the transistor 500 can be separated by a barrier layer. Thus, the hydrogen diffusion from the transistor 550 into the transistor 500 can be inhibited.

A wiring layer may be provided over the insulator 374 and the conductor 376. For example, an insulator 380, an insulator 382, and an insulator 384 are stacked sequentially in FIG. 11. Furthermore, a conductor 386 is formed in the insulator 380, the insulator 382, and the insulator 384. The conductor 386 has a function of a plug or a wiring. Note that the conductor 386 can be formed using a material similar to that for the conductor 328 and the conductor 330.

Note that for example, the insulator 380 is preferably formed using an insulator having a barrier property against hydrogen, like the insulator 324. Furthermore, the conductor 386 preferably includes a conductor having a barrier property against hydrogen. The conductor having a barrier property against hydrogen is formed particularly in an opening portion of the insulator 380 having a barrier property against hydrogen. In such a structure, the transistor 550 and the transistor 500 can be separated by a barrier layer. Thus, the hydrogen diffusion from the transistor 550 into the transistor 500 can be inhibited.

Although the example where the wiring layer similar to the wiring layer including the conductor 356 has a four-layer structure, that is, the wiring layer including the conductor 356, the wiring layer including the conductor 366, the wiring layer including the conductor 376, and the wiring layer including the conductor 386 are described above, the semiconductor device of this embodiment is not limited thereto. Three or less wiring layers that are similar to the wiring layer including the conductor 356 may be provided, or five or more wiring layers that are similar to the wiring layer including the conductor 356 may be provided.

An insulator 510, an insulator 512, an insulator 514, and an insulator 516 are stacked sequentially over the insulator 384. For example, a material having a barrier property against oxygen and hydrogen is preferably used for any of the insulator 510, the insulator 512, the insulator 514, and the insulator 516.

For example, each of the insulator 510 and the insulator 514 is preferably formed using a film having a barrier property which prevents hydrogen, impurities, or the like from diffusing from the substrate 311, a region where the transistor 550 is provided, or the like into a region where the transistor 500 is provided. Therefore, for each of the insulator 510 and the insulator 514, a material similar to that for the insulator 324 can be used.

For the film having a barrier property against hydrogen, for example, silicon nitride deposited by a CVD method can be used. For example, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. Specifically, the film that inhibits hydrogen diffusion is a film from which a small amount of hydrogen is released.

For the film having a barrier property against hydrogen used for each of the insulator 510 and the insulator 514, for example, a metal oxide such as aluminum oxide, hafnium oxide, or tantalum oxide is preferably used.

In particular, aluminum oxide has an excellent blocking effect that prevents permeation of both oxygen and impurities such as hydrogen and moisture that cause a change in electrical characteristics of the transistor, for example. Accordingly, the use of aluminum oxide can prevent entry of impurities, for example, hydrogen or moisture into the transistor 500 during and after a manufacturing process of the transistor. In addition, aluminum oxide can inhibit release of oxygen from an oxide contained in the transistor 500. Therefore, aluminum oxide is suitably used for a protective film of the transistor 500.

The insulator 512 and the insulator 516 can be formed using a material similar to that for the insulator 320, for example. In the case where a material with a relatively low dielectric constant is used for these insulators, the parasitic capacitance generated between wirings can be reduced. A silicon oxide film, a silicon oxynitride film, or the like can be used for the insulator 512 and the insulator 516, for example.

A conductor 518, a conductor included in the transistor 500 (e.g., a conductor 503), and the like are embedded in the insulator 510, the insulator 512, the insulator 514, and the insulator 516, for example. Note that the conductor 518 has a function of a plug or a wiring that is connected to the capacitor 600 or the transistor 550. The conductor 518 can be formed using a material similar to that for the conductor 328 and the conductor 330.

In particular, the conductor 518 in a region in contact with the insulator 510 and the insulator 514 is preferably a conductor having a barrier property against oxygen, hydrogen, and water. In such a structure, the transistor 550 and the transistor 500 can be separated by a layer having a barrier property against oxygen, hydrogen, and water, so that the hydrogen diffusion from the transistor 550 into the transistor 500 can be inhibited.

The transistor 500 is provided over the insulator 516.

As illustrated in FIG. 12A and FIG. 12B, the transistor 500 includes the conductor 503 provided so as to be embedded in the insulator 514 and the insulator 516, an insulator 520 provided over the insulator 516 and the conductor 503, an insulator 522 provided over the insulator 520, an insulator 524 provided over the insulator 522, an oxide 530a provided over the insulator 524, an oxide 530b provided over the oxide 530a, a conductor 542a and a conductor 542b provided apart from each other over the oxide 530b, an insulator 580 that is provided over the conductor 542a and the conductor 542b and has an opening overlapping with a region between the conductor 542a and the conductor 542b, an insulator 545 provided on a bottom surface and a side surface of the opening, and a conductor 560 that is provided on a formation surface of the insulator 545.

As illustrated in FIG. 12A and FIG. 12B, an insulator 544 is preferably provided between the insulator 580 and the oxide 530a, the oxide 530b, the conductor 542a, and the conductor 542b. In addition, as illustrated in FIG. 12A and FIG. 12B, the conductor 560 preferably includes a conductor 560a provided inside the insulator 545 and a conductor 560b provided to be embedded inside the conductor 560a. Moreover, as illustrated in FIG. 12A and FIG. 12B, an insulator 574 is preferably provided over the insulator 580, the conductor 560, and the insulator 545. In this specification and the like, the oxide 530a and the oxide 530b may be collectively referred to as an oxide 530.

The transistor 500 has, in the region where the channel is formed and its vicinity, a structure in which two layers, the oxide 530a and the oxide 530b, are stacked; however, one embodiment of the present invention is not limited thereto. For example, a single layer of the oxide 530b or a stacked-layer structure of three or more layers may be provided in the region where a channel is formed and its vicinity.

Although the conductor 560 has a stacked-layer structure of two layers in the transistor 500, one embodiment of the present invention is not limited thereto. For example, the conductor 560 may have a single-layer structure or a stacked-layer structure of three or more layers. The transistor 500 illustrated in FIG. 11 and FIG. 12A is just an example and is not limited to the structure illustrated therein, and an appropriate transistor can be used in accordance with a circuit structure or a driving method, for example.

Here, the conductor 560 functions as a gate electrode of the transistor, and the conductor 542a and the conductor 542b function as a source electrode and a drain electrode. As described above, the conductor 560 is formed to be embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be provided between the source electrode and the drain electrode in a self-aligned manner. Therefore, the conductor 560 can be formed without an alignment margin. Thus, the area occupied by the transistor 500 can be reduced. Accordingly, miniaturization and high integration of the semiconductor device can be achieved.

In addition, since the conductor 560 is formed in the region between the conductor 542a and the conductor 542b in a self-aligned manner, the conductor 560 has neither a region overlapping with the conductor 542a nor a region overlapping with the conductor 542b. Thus, parasitic capacitance formed between the conductor 560 and each of the conductor 542a and the conductor 542b can be reduced. As a result, the transistor 500 can have increased switching speed and excellent frequency characteristics.

Here, the conductor 560 functions as a first gate (also referred to as a top gate) electrode in some cases. The conductor 503 functions as a second gate (also referred to as a bottom gate) electrode in some cases. In that case, in the transistor 500, by changing a potential applied to the conductor 503 independently of a potential applied to the conductor 560, the threshold voltage of the transistor 500 can be controlled. In particular, when a negative potential is applied to the conductor 503, the threshold voltage of the transistor 500 can be increased, and the off-state current can be reduced. Thus, a drain current when a potential applied to the conductor 560 is 0 V can be smaller in the case where a negative potential is applied to the conductor 503 than in the case where the negative potential is not applied to the conductor 503.

The conductor 503 is provided to overlap with the oxide 530 and the conductor 560. Accordingly, in the case where potentials are applied to the conductor 560 and the conductor 503, an electric field generated from the conductor 560 and an electric field generated from the conductor 503 are connected, thereby covering the channel formation region formed in the oxide 530.

In this specification and the like, a transistor structure in which a channel formation region is electrically surrounded by the electric field of a first gate electrode is referred to as a surrounded channel (S-channel) structure. The S-channel structure disclosed in this specification and the like has a structure different from a Fin-type structure or a planar structure. The S-channel structure disclosed in this specification and the like can be regarded as a kind of the Fin-type structure. In this specification and the like, the Fin-type structure refers to a structure in which at least two surfaces (specifically, two surfaces, three surfaces, four surfaces, or the like) of a channel are covered with a gate electrode. With the use of the Fin-type structure or the S-channel structure, a transistor with high resistance to a short-channel effect can be obtained. In other words, a transistor in which a short-channel effect is unlikely to occur, can be obtained.

When the transistor has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. In the transistor having any of the S-channel structure, GAA structure, and LGAA structure, the channel formation region that is formed at the interface between the oxide 530 and the gate insulator or in the vicinity of the interface can be formed in the entire bulk of the oxide 530. Accordingly, the density of current flowing through the transistor can be improved, which can be expected to improve the on-state current of the transistor or increase the field-effect mobility of the transistor.

The conductor 503 has a structure similar to that of the conductor 518; a conductor 503a is formed in contact with an inner wall of the opening in the insulator 514 and the insulator 516, and a conductor 503b is formed on the inner side. Although the transistor 500 having a structure in which the conductor 503a and the conductor 503b are stacked is described, one embodiment of the present invention is not limited thereto. For example, the conductor 503 may have a single-layer structure or a stacked-layer structure of three or more layers.

Here, for the conductor 503a, a conductive material having a function of inhibiting diffusion of impurities such as a hydrogen atom, a hydrogen molecule, a water molecule, or a copper atom (a conductive material through which the above impurities are less likely to pass) is preferably used, for example. Alternatively, for the conductor 503a, a conductive material having a function of inhibiting diffusion of oxygen (e.g., at least one of oxygen atoms, oxygen molecules, and the like) (a conductive material through which the above oxygen is less likely to pass) is preferably used. Note that in this specification and the like, a function of inhibiting diffusion of impurities or oxygen means a function of inhibiting diffusion of any one or all of the above impurities and the above oxygen.

For example, when the conductor 503a has a function of inhibiting diffusion of oxygen, the conductivity of the conductor 503b can be prevented from being lowered because of oxidation.

In the case where the conductor 503 also functions as a wiring, the conductor 503b is preferably formed using a conductive material with high conductivity that contains tungsten, copper, or aluminum as its main component. Although the conductor 503 has a stacked layer of the conductor 503a and the conductor 503b in this embodiment, the conductor 503 may have a single-layer structure.

The insulator 520, the insulator 522, and the insulator 524 have a function of a second gate insulating film.

Here, an insulator containing oxygen more than that in the stoichiometric composition is preferably used as the insulator 524 in contact with the oxide 530. Such oxygen is easily released from the film by heating. In this specification and the like, oxygen released by heating is sometimes referred to as “excess oxygen”. That is, a region containing excess oxygen (also referred to as an “excess-oxygen region”) is preferably formed in the insulator 524. When such an insulator containing excess oxygen is provided in contact with the oxide 530, oxygen vacancies (also referred to as V_{O}) in the oxide 530 can be reduced, leading to an improvement in reliability of the transistor 500. When hydrogen enters the oxygen vacancies in the oxide 530, such defects (hereinafter, referred to as V_{O}H in some cases) serve as donors and generate electrons serving as carriers in some cases. In other cases, bonding of part of hydrogen to oxygen bonded to a metal atom generates electrons serving as carriers. Thus, a transistor including an oxide semiconductor that contains a large amount of hydrogen is likely to have normally-on characteristics. Moreover, hydrogen in an oxide semiconductor is easily transferred by a stress such as heat or an electric field, for example; thus, a large amount of hydrogen in an oxide semiconductor might reduce the reliability of a transistor. In one embodiment of the present invention, V_{O}H in the oxide 530 is preferably reduced as much as possible so that the oxide 530 becomes a highly purified intrinsic or substantially highly purified intrinsic oxide. In order to obtain such an oxide semiconductor with sufficiently reduced V_{O}H, it is important to remove impurities such as moisture and hydrogen in the oxide semiconductor (this treatment is also referred to as “dehydration” or “dehydrogenation treatment”) and supply oxygen to the oxide semiconductor to fill oxygen vacancies (this treatment is also referred to as “oxygen adding treatment”). For example, when an oxide semiconductor with sufficiently reduced impurities such as V_{O}H is used for a channel formation region of a transistor, stable electrical characteristics can be given.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm₃ in TDS (Thermal Desorption Spectroscopy) analysis. In the TDS analysis, the film-surface temperature is preferably within the range of higher than or equal to 100° C. and lower than or equal to 700° C., or higher than or equal to 100° C. and lower than or equal to 400° C.

One or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of V_{O}H is cut occurs. In other words, in the oxide 530, dehydrogenation can be performed when a reaction of “V_{O}H→V_{O}+H” occurs. Part of hydrogen generated at this time is bonded to oxygen to be H₂O, and is removed from the oxide 530 or an insulator near the oxide 530 in some cases. In other cases, part of hydrogen is gettered by one or both of the conductor 542a and the conductor 542b.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The microwave treatment is performed under a pressure of 133 Pa or higher, preferably 200 Pa or higher, further preferably 400 Pa or higher. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In a manufacturing process of the transistor 500, the heat treatment is preferably performed with the surface of the oxide 530 exposed. For example, the heat treatment is performed at higher than or equal to 100° C. and lower than or equal to 450° C., preferably higher than or equal to 350° C. and lower than or equal to 400° C. The heat treatment is performed in a nitrogen gas atmosphere, an inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 530 to reduce oxygen vacancies (V_{O}). The heat treatment may be performed under a reduced pressure. Alternatively, the heat treatment may be performed in such a manner that heat treatment is performed in a nitrogen gas atmosphere or an inert gas atmosphere, and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is successively performed in a nitrogen gas atmosphere or an inert gas atmosphere.

Note that the oxygen adding treatment performed on the oxide 530 can promote a reaction in which oxygen vacancies in the oxide 530 are filled with supplied oxygen, i.e., a reaction of “V_{O}+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of V_{O}H.

In the case where the insulator 524 includes an excess-oxygen region, the insulator 522 preferably has a function of inhibiting diffusion of oxygen (e.g., at least one of oxygen atoms and oxygen molecules) (it is preferable that oxygen be less likely to pass through the insulator 522).

The insulator 522 preferably has a function of inhibiting diffusion of oxygen, impurities, or the like, in which case diffusion of oxygen contained in the oxide 530 to the insulator 520 side is prevented. In addition, the conductor 503 can be inhibited from reacting with oxygen in the insulator 524 or the oxide 530, for example.

For the insulator 522, an insulator of a high dielectric constant (high-k) material (a material with a high relative dielectric constant) is preferably used. For the insulator 522, it is preferable to use a single layer or stacked layers of an insulator containing aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST), for example. As miniaturization and high integration of transistors progress, a problem such as leakage current sometimes arises because of a thin gate insulating film, for example. When a high-k material is used for an insulator functioning as the gate insulating film, a gate potential at the time of operating the transistor can be reduced while the physical thickness of the gate insulating film is kept.

It is particularly preferable to use an insulator containing an oxide of one or both of aluminum and hafnium, which is an insulating material having a function of inhibiting diffusion of impurities and oxygen (an insulating material through which the above oxygen is less likely to pass), for example. As the insulator containing an oxide of one or both of aluminum and hafnium, for example, aluminum oxide, hafnium oxide, or an oxide containing aluminum and hafnium (hafnium aluminate) is preferably used, for example. In the case where the insulator 522 is formed using such a material, the insulator 522 functions as a layer that inhibits release of oxygen from the oxide 530 or entry of impurities, for example, hydrogen or the like, from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over any of the above insulators.

It is preferable that the insulator 520 be thermally stable. For example, silicon oxide and silicon oxynitride are preferred because of their thermal stability. Furthermore, combination of an insulator which is a high-k material and silicon oxide or silicon oxynitride enables the insulator 520 to have a stacked-layer structure that is thermally stable and has a high relative dielectric constant.

Note that the transistor 500 in FIG. 12A and FIG. 12B includes the insulator 520, the insulator 522, and the insulator 524 as the second gate insulating film having a stacked-layer structure of three layers; however, the second gate insulating film may have a single-layer structure, a two-layer structure, or a stacked-layer structure of four or more layers. In that case, the second gate insulating film is not limited to a stacked-layer structure formed of the same material, and may be a stacked-layer structure formed of different materials.

In the transistor 500, a metal oxide functioning as an oxide semiconductor is used as the oxide 530 including a channel formation region. As the oxide 530, a metal oxide containing indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc is preferably used, for example.

The metal oxide functioning as an oxide semiconductor may be formed by a sputtering method or an ALD (atomic layer deposition) method. Note that the metal oxide functioning as an oxide semiconductor will be described in detail in another embodiment.

The metal oxide functioning as the channel formation region in the oxide 530 has a band gap of 2 eV or more, preferably 2.5 eV or more. The use of a metal oxide having such a wide band gap as the oxide 530 can reduce the off-state current of the transistor 500.

When the oxide 530a is provided below the oxide 530b in the oxide 530, impurities can be inhibited from diffusing into the oxide 530b from the components formed below the oxide 530a.

The oxide 530 preferably has a structure including a plurality of oxide layers that differ in the atomic ratio of metal atoms. Specifically, the atomic ratio of the element M to constituent elements in the metal oxide used as the oxide 530a is preferably greater than that in the metal oxide used as the oxide 530b. Moreover, the atomic ratio of the element M to In in the metal oxide used as the oxide 530a is preferably greater than that in the metal oxide used as the oxide 530b. Moreover, the atomic ratio of In to the element M in the metal oxide used as the oxide 530b is preferably greater than that in the metal oxide used as the oxide 530a.

The energy of the conduction band minimum of the oxide 530a is preferably higher than that of the oxide 530b. In other words, the electron affinity of the oxide 530a is preferably smaller than that of the oxide 530b.

Here, the energy level of the conduction band minimum gradually changes at a junction portion of the oxide 530a and the oxide 530b. In other words, the energy level of the conduction band minimum at a junction portion of the oxide 530a and the oxide 530b is continuously changed or continuously connected. To change the energy level gradually, the density of defect states in a mixed layer formed at the interface between the oxide 530a and the oxide 530b is preferably made low.

Specifically, when the oxide 530a and the oxide 530b contain the same element (as a main component) in addition to oxygen, a mixed layer with a low density of defect states can be formed. For example, in the case where the oxide 530b is In—Ga—Zn oxide, it is preferable to use In—Ga—Zn oxide, Ga—Zn oxide, gallium oxide, or the like as the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and the conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements as its component; or an alloy containing a combination of the above metal elements; for example. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, or an oxide containing lanthanum and nickel is preferable because they are oxidation-resistant conductive materials or materials that maintain their conductivity even after absorbing oxygen. Furthermore, for example, a metal nitride film such as a tantalum nitride film is preferable because it has a barrier property against hydrogen or oxygen.

In addition, although the conductor 542a and the conductor 542b each having a single-layer structure are illustrated in FIG. 12A, a stacked-layer structure of two or more layers may be employed. For the conductor 542a and the conductor 542b, a tantalum nitride film and a tungsten film are preferably stacked, for example. Alternatively, for the conductor 542a and the conductor 542b, a titanium film and an aluminum film may be stacked, for example. For the conductor 542a and the conductor 542b, a two-layer structure in which an aluminum film is stacked over a tungsten film, a two-layer structure in which a copper film is stacked over a copper-magnesium-aluminum alloy film, a two-layer structure in which a copper film is stacked over a titanium film, or a two-layer structure in which a copper film is stacked over a tungsten film may be employed, for example.

For the conductor 542a and the conductor 542b, a three-layer structure consisting of a titanium film or a titanium nitride film, an aluminum film or a copper film stacked over the titanium film or the titanium nitride film, and a titanium film or a titanium nitride film formed thereover; or a three-layer structure consisting of a molybdenum film or a molybdenum nitride film, an aluminum film or a copper film stacked over the molybdenum film or the molybdenum nitride film, and a molybdenum film or a molybdenum nitride film formed thereover may be employed, for example. Note that a transparent conductive material containing indium oxide, tin oxide, or zinc oxide may be used for the conductor 542a and the conductor 542b, for example.

As illustrated in FIG. 12A, a region 543a and a region 543b are sometimes formed as low-resistance regions at and near the interface between the oxide 530 and the conductor 542a (the conductor 542b). In that case, the region 543a functions as one of a source region and a drain region, and the region 543b functions as the other of the source region and the drain region. A channel formation region is formed in a region sandwiched between the region 543a and the region 543b.

When the conductor 542a (the conductor 542b) is provided in contact with the oxide 530, the oxygen concentration in the region 543a (the region 543b) sometimes decrease. In addition, a metal compound layer that contains the metal contained in the conductor 542a (the conductor 542b) and the component of the oxide 530 is sometimes formed in the region 543a (the region 543b). In such cases, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. Here, the insulator 544 may be provided to cover a side surface of the oxide 530 and to be in contact with the insulator 524.

A metal oxide containing one or two or more kinds selected from hafnium, aluminum, gallium, yttrium, zirconium, tungsten, titanium, tantalum, nickel, germanium, neodymium, lanthanum, magnesium, and the like can be used for the insulator 544, for example. For the insulator 544, silicon nitride oxide or silicon nitride can be used, for example.

For the insulator 544, it is particularly preferable to use an insulator containing an oxide of one or both of aluminum and hafnium, for example, aluminum oxide, hafnium oxide, or an oxide containing aluminum and hafnium (hafnium aluminate). In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose the conductivity even after absorbing oxygen. Design of the insulator 544 is appropriately set in consideration of required transistor characteristics.

With the insulator 544, impurities such as water and hydrogen contained in the insulator 580 from diffusing into the oxide 530b can be inhibited. Moreover, the oxidation of the conductor 542a and the conductor 542b due to excess oxygen contained in the insulator 580 can be inhibited.

The insulator 545 functions as a first gate insulating film. The insulator 545 is preferably formed using an insulator which contains excess oxygen and from which oxygen is released by heating, like the insulator 524.

Specifically, any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide each containing excess oxygen can be used. In particular, silicon oxide and silicon oxynitride, which have thermal stability, are preferable.

When an insulator containing excess oxygen is provided as the insulator 545, oxygen can be effectively supplied from the insulator 545 to the channel formation region of the oxide 530b. As in the insulator 524, the concentration of impurities such as water and hydrogen in the insulator 545 is preferably lowered. The thickness of the insulator 545 is preferably greater than or equal to 1 nm and less than or equal to 20 nm.

Furthermore, in order that excess oxygen contained in the insulator 545 can be efficiently supplied to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen between the insulator 545 and the conductor 560 inhibits diffusion of excess oxygen from the insulator 545 into the conductor 560. That is, a reduction in the amount of excess oxygen supplied to the oxide 530 can be suppressed. Moreover, oxidization of the conductor 560 due to excess oxygen can be suppressed. The metal oxide is formed using a material that can be used for the insulator 544.

Note that the insulator 545 may have a stacked-layer structure like the second gate insulating film. As miniaturization and high integration of transistors progress, a problem such as leakage current sometimes arises because of a thin gate insulating film, for example. Thus, when the insulator 545 functioning as a gate insulating film has a stacked-layer structure of a high-k material and a thermally stable material, a gate potential at the time of operating the transistor 500 can be reduced while the physical thickness of the insulator 545 is kept. Furthermore, the insulator 545 can have a stacked-layer structure with thermally stable and with a high relative dielectric constant.

Although the conductor 560 functioning as the first gate electrode has a two-layer structure (the conductor 560a and the conductor 560b) in FIG. 12A and FIG. 12B, the conductor 560 may have a single-layer structure or a stacked-layer structure of three or more layers.

The conductor 560a is preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 560a is preferably formed using a conductive material having a function of inhibiting diffusion of oxygen (e.g., at least one of oxygen atoms, oxygen molecules, and the like). When the conductor 560a has a function of inhibiting diffusion of oxygen, the conductivity of the conductor 560b can be prevented from being lowered because of oxidization due to oxygen contained in the insulator 545. As the conductive material having a function of inhibiting diffusion of oxygen, for example, tantalum, tantalum nitride, ruthenium, ruthenium oxide, or the like is preferably used. The conductor 560a can be formed using an oxide semiconductor that can be used for the oxide 530. In that case, when the conductor 560b is formed by a sputtering method, the conductor 560a can have a reduced electric resistance value and become a conductor. Such a conductor can be referred to as an OC (Oxide Conductor) electrode.

Furthermore, the conductor 560b is preferably formed using a conductive material containing tungsten, copper, or aluminum as its main component. The conductor 560b also functions as a wiring and thus is preferably a conductor having high conductivity. For example, a conductive material containing tungsten, copper, or aluminum as its main component can be used. The conductor 560b may have a stacked-layer structure. For example, the conductor 560b may have a stacked-layer structure of titanium or titanium nitride and any of the above conductive materials.

The insulator 580 is provided over the conductor 542a and the conductor 542b with the insulator 544 therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide and silicon oxynitride, which have thermal stability, are preferable. Silicon oxide and porous silicon oxide are particularly preferable because an excess-oxygen region can be formed easily in a later step.

The insulator 580 preferably includes an excess-oxygen region. When the insulator 580 from which oxygen is released by heating is provided, oxygen in the insulator 580 can be efficiently supplied to the oxide 530. The concentration of impurities such as water and hydrogen in the insulator 580 is preferably lowered.

The opening of the insulator 580 is formed to overlap with a region between the conductor 542a and the conductor 542b. Thus, the conductor 560 is formed to be embedded in the opening of the insulator 580 and the region sandwiched between the conductor 542a and the conductor 542b.

The gate length needs to be short for miniaturization of the semiconductor device without a reduction in the conductivity of the conductor 560. When the conductor 560 is made thick to achieve this, the conductor 560 might have a shape with a high aspect ratio. In this embodiment, the conductor 560 is provided to be embedded in the opening of the insulator 580. Thus, even when the conductor 560 has a shape with a high aspect ratio, the conductor 560 can be formed without collapsing during the process.

The insulator 574 is preferably provided in contact with the top surface of the insulator 580, the top surface of the conductor 560, and the top surface of the insulator 545. When the insulator 574 is formed by a sputtering method, the insulator 545 and the insulator 580 can include an excess-oxygen region. Therefore, oxygen can be supplied from the excess-oxygen region to the oxide 530.

For example, a metal oxide containing one or two or more kinds selected from hafnium, aluminum, gallium, yttrium, zirconium, tungsten, titanium, tantalum, nickel, germanium, magnesium, and the like can be used for the insulator 574.

In particular, aluminum oxide has a high barrier property, and even a thin aluminum oxide film having a thickness greater than or equal to 0.5 nm and less than or equal to 3.0 nm can inhibit diffusion of hydrogen and nitrogen. Thus, aluminum oxide deposited by a sputtering method can serve as not only an oxygen supply source but also a barrier film against impurities such as hydrogen, for example.

An insulator 581 functioning as an interlayer film is preferably provided over the insulator 574. As in the insulator 524 or the like, the concentration of impurities such as water and hydrogen in the insulator 581 is preferably lowered, for example.

A conductor 540a and a conductor 540b are provided in the openings formed in the insulator 581, the insulator 574, the insulator 580, and the insulator 544. The conductor 540a and the conductor 540b are provided to face each other with the conductor 560 therebetween. The conductor 540a and the conductor 540b have a structure similar to that of a conductor 546 and a conductor 548 described later.

An insulator 582 is provided over the insulator 581. For example, a material having a barrier property against oxygen, hydrogen, and the like is preferably used for the insulator 582. Thus, the insulator 582 can be formed using a material similar to that for the insulator 514. For the insulator 582, a metal oxide such as aluminum oxide, hafnium oxide, or tantalum oxide is preferably used, for example.

In particular, aluminum oxide has an excellent blocking effect that prevents permeation of oxygen and impurities such as hydrogen and moisture that cause a change in electrical characteristics of the transistor. Accordingly, the use of aluminum oxide can prevent entry of impurities such as hydrogen and moisture into the transistor 500 during and after a manufacturing process of the transistor. In addition, release of oxygen from the oxide contained in the transistor 500 can be prevented. Therefore, aluminum oxide is suitably used for a protective film of the transistor 500.

An insulator 586 is provided over the insulator 582. The insulator 586 can be formed using a material similar to that for the insulator 320. In the case where a material with a relatively low dielectric constant is used for these insulators, the parasitic capacitance generated between wirings can be reduced. For example, a silicon oxide film, a silicon oxynitride film, or the like can be used for the insulator 586.

For example, the conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have a function of plugs or wirings that are connected to the capacitor 600, the transistor 500, or the transistor 550. The conductor 546 and the conductor 548 can be formed using a material similar to that for the conductor 328 and the conductor 330.

After the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, the formation of an opening reaching the insulator 522 or the insulator 514 and the formation of the insulator having a high barrier property in contact with the insulator 522 or the insulator 514 are suitable because these formation steps can also serve as some of the manufacturing steps of the transistor 500. The insulator having a high barrier property against hydrogen or water is formed using a material similar to that for the insulator 522 or the insulator 514, for example.

The capacitor 600 is provided above the transistor 500. The capacitor 600 includes a conductor 610, a conductor 620, and an insulator 630.

A conductor 612 may be provided over the conductor 546 and the conductor 548. The conductor 612 functions as a plug or a wiring that is connected to the transistor 500. The conductor 610 has a function of an electrode of the capacitor 600. The conductor 612 and the conductor 610 can be formed at the same time.

For the conductor 612 and the conductor 610, a metal film containing an element selected from molybdenum, titanium, tantalum, tungsten, aluminum, copper, chromium, neodymium, and scandium; or a metal nitride film containing any of the above elements as its component (a tantalum nitride film, a titanium nitride film, a molybdenum nitride film, or a tungsten nitride film) can be used, for example. Alternatively, for the conductor 612 and the conductor 610, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added, for example.

The conductor 612 and the conductor 610 each have a single-layer structure in this embodiment; however, the structure is not limited thereto, and the conductor 612 and the conductor 610 may each have a stacked-layer structure of two or more layers. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 therebetween. Note that a conductive material such as a metal material, an alloy material, or a metal oxide material can be used for the conductor 620, for example. For the conductor 620, it is preferable to use a high-melting point material that has both heat resistance and conductivity, such as tungsten or molybdenum, and it is particularly preferable to use tungsten. In the case where the conductor 620 is formed concurrently with another component such as another conductor, copper, aluminum, or the like, which is a low-resistance metal material, is used, for example.

An insulator 640 is provided over the conductor 620 and the insulator 630. The insulator 640 can be formed using a material similar to that for the insulator 320. The insulator 640 may function as a planarization film that covers a roughness thereunder.

With the use of the structure, a semiconductor device that includes a transistor including an oxide semiconductor can be miniaturized or highly integrated.

Note that, examples of a substrate that can be used for the semiconductor device of one embodiment of the present invention include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and an SOI (Silicon on Insulator) substrate. Alternatively, a plastic substrate having heat resistance to the processing temperature in this embodiment may be used as the substrate. Examples of the glass substrate include a barium borosilicate glass substrate, an aluminosilicate glass substrate, an aluminoborosilicate glass substrate, and a soda lime glass substrate. Alternatively, crystallized glass or the like may be used for the glass substrate, for example.

Alternatively, a flexible substrate; an attachment film; paper or a base film including a fibrous material; or the like can be used as the substrate, for example. Examples of the flexible substrate, the attachment film, the base material film, and the like, include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Other examples include polyamide, polyimide, an aramid resin, an epoxy resin, an inorganic vapor deposition film, and paper. Specifically, for example, the use of a semiconductor substrate, a single crystal substrate, an SOI substrate, or the like for the manufacture of transistors enables the manufacture of small-sized transistors with a small variation in characteristics, size, shape, or the like and with high current capability. When a circuit is formed with such transistors, lower power consumption of the circuit or higher integration of the circuit can be achieved.

A flexible substrate may be used as the substrate, and one or more of a transistor, a resistor, a capacitor, and the like may be formed directly over the flexible substrate, for example. Alternatively, a separation layer may be provided between the substrate and one or more of the transistor, the resistor, the capacitor, and the like. After part or the whole of a semiconductor device is completed over the separation layer, the separation layer can be used for separation from the substrate and transfer to another substrate. In such a case, for example, one or more of the transistor, the resistor, the capacitor, and the like can be transferred to a substrate having low heat resistance, a flexible substrate, or the like. As the separation layer, a stacked-layer structure of a tungsten film and a silicon oxide film that are inorganic films, a structure in which an organic resin film of polyimide or the like is formed over a substrate, a silicon film containing hydrogen, or the like can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, a flexible semiconductor device or a highly durable semiconductor device can be manufactured. Provision of heat resistance to the semiconductor device can be achieved. A reduction in weight or thickness of the semiconductor device can be achieved.

Providing a semiconductor device over a flexible substrate can suppress an increase in weight and can produce a non-breakable semiconductor device.

Note that the transistor 550 illustrated in FIG. 11 is an example and the structure is not limited thereto; an appropriate transistor is used in accordance with a circuit structure or a driving method, for example. For example, when the semiconductor device is a single-polarity circuit using only OS transistors (which means a circuit including only n-channel transistors or a circuit including only p-channel transistors, for example), the transistor 550 has a structure similar to that of the transistor 500.

The structures, configurations, methods, and the like described in this embodiment can be used in combination as appropriate with the structures, configurations, methods, and the like described in the other embodiments and the like.

### Embodiment 4

In this embodiment, cross-sectional structure examples of a memory device including OS transistors described in the above embodiments, such as a DOSRAM and a NOSRAM, will be described.

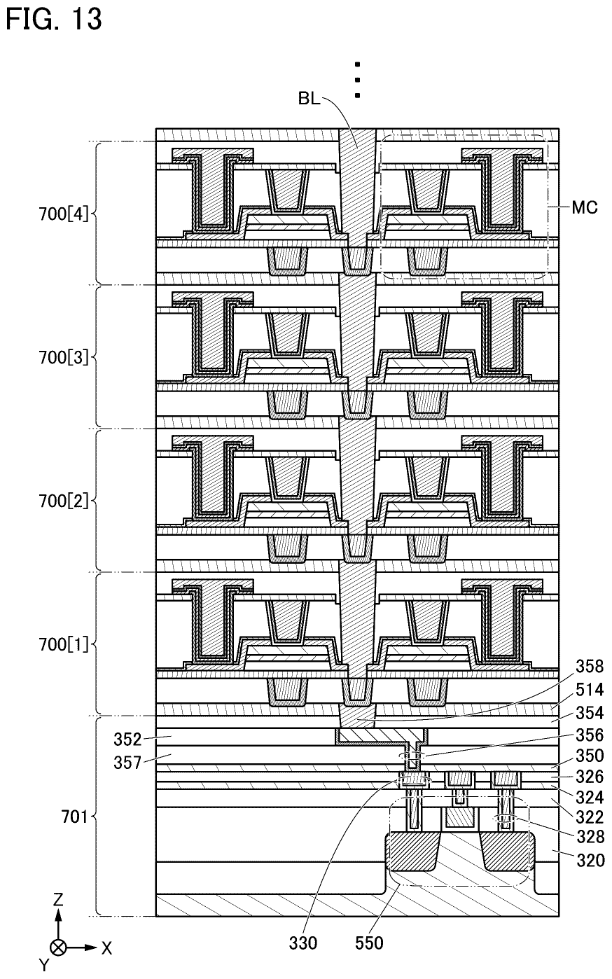

FIG. 13 illustrates a cross-sectional structure example of the case of using a DOSRAM circuit structure. In the example illustrated in FIG. 13, a memory layer 700[1] to a memory layer 700[4] are stacked over a driver circuit layer 701.

FIG. 13 illustrates the transistor 550 included in the driver circuit layer 701 as an example. The transistor 550 described in the above embodiment can be used as the transistor 550. Thus, the above description of the transistor 550 can be referred to as appropriate.

The transistor 550 illustrated in FIG. 13 is just an example and is not limited to the structure illustrated therein, and an appropriate transistor can be used in accordance with a circuit structure or a driving method.

A wiring layer provided with an interlayer film, a wiring, a plug, and the like may be provided between the driver circuit layer 701 and the memory layers 700 or between a k-th memory layer 700 and a (k+1)-th memory layer 700, for example. In this embodiment and the like, the k-th memory layer 700 is referred to as the memory layer 700[k], and the (k+1)-th memory layer 700 is referred to as the memory layer 700[k+1], in some cases. Here, k is an integer greater than or equal to 1.

A plurality of wiring layers can be provided in accordance with the design. Furthermore, in this specification and the like, a wiring and a plug electrically connected to the wiring may be a single component. That is, part of a conductor functions as a wiring and part of a conductor functions as a plug in other cases.

For example, the insulator 320, the insulator 322, the insulator 324, and the insulator 326 are stacked in this order over the transistor 550 as interlayer films. For example, the conductor 328 or the like is embedded in the insulator 320 and the insulator 322. For example, the conductor 330 or the like is embedded in the insulator 324 and the insulator 326. Note that the conductor 328 and the conductor 330 each function as a contact plug or a wiring.

The insulator functioning as an interlayer film may function as a planarization film that covers a roughness thereunder. For example, the top surface of the insulator 320 may be planarized by planarization treatment using a chemical mechanical polishing (CMP) method or the like to increase the level of planarity.

A wiring layer may be provided over the insulator 326 and the conductor 330. For example, in FIG. 13, the insulator 350, an insulator 357, the insulator 352, and the insulator 354 are stacked in this order over the insulator 326 and the conductor 330. The conductor 356 is formed in the insulator 350, the insulator 357, and the insulator 352. The conductor 356 functions as a contact plug or a wiring.

Over the insulator 354, the insulator 514 included in the memory layer 700[1] is provided. A conductor 358 is embedded in the insulator 514 and the insulator 354. The conductor 358 functions as a contact plug or a wiring. For example, the bit line BL and the transistor 550 are electrically connected to each other through the conductor 358, the conductor 356, the conductor 330, and the like.

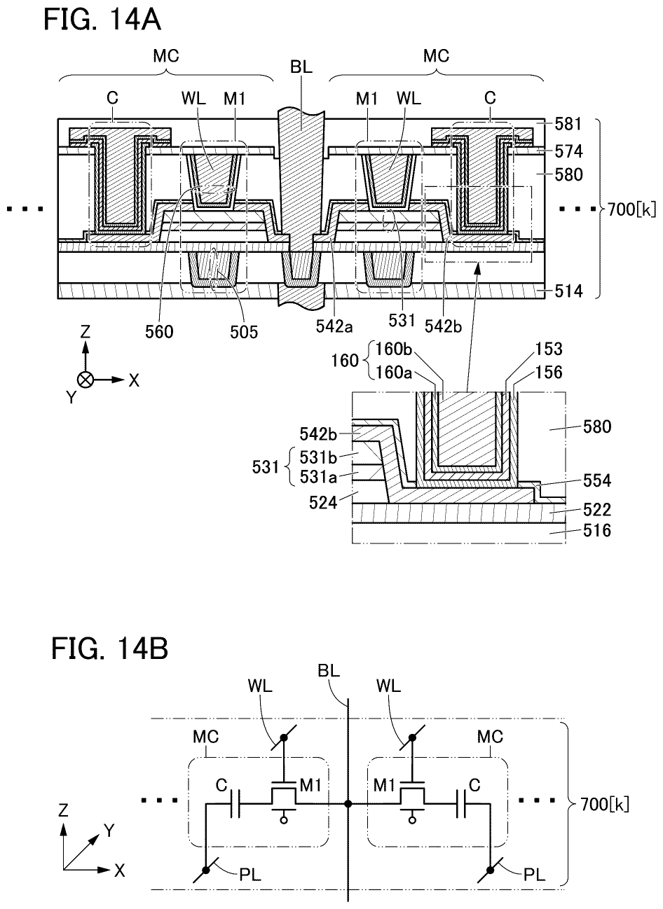

FIG. 14A illustrates a cross-sectional structure example of the memory layer 700[k]. FIG. 14B is an equivalent circuit diagram of FIG. 14A. FIG. 14A illustrates an example where two memory cells MC are electrically connected to one bit line BL.

The memory cell MC illustrated in each of FIG. 13, FIG. 14A, and FIG. 14B includes the transistor M1 and the capacitor C. As the transistor M1, the transistor 500 described in the above embodiment can be used. Thus, the above description of the transistor 500 can be referred to as appropriate.

In this embodiment, a variation example of the transistor 500 is illustrated as the transistor M1. Specifically, the transistor M1 is different from the transistor 500 in that the conductor 542a and the conductor 542b extend beyond an end portion of a metal oxide 531 (an oxide 531a and an oxide 531b).

The memory cell MC illustrated in each of FIG. 13, FIG. 14A, and FIG. 14B corresponds to the memory cell MC illustrated in FIG. 5D in the above embodiment, for example. Therefore, the above description of FIG. 5D can be referred to as appropriate.

The memory cell MC illustrated in each of FIG. 13 and FIG. 14A includes a conductor 156 functioning as one terminal of the capacitor C, an insulator 153 functioning as a dielectric, and a conductor 160 (a conductor 160a and a conductor 160b) functioning as the other terminal of the capacitor C. The conductor 156 is electrically connected to part of the conductor 542b. The conductor 160 is electrically connected to a wiring PL (not illustrated in FIG. 14A).

One of the source and the drain of the transistor M1 is electrically connected to part of the conductor 542b. The other of the source and the drain of the transistor M1 is electrically connected to part of the conductor 542a. The gate of the transistor M1 is electrically connected to the word line WL. Part of the conductor 542a is electrically connected to the bit line BL.

The capacitor C is formed in an opening portion that is provided by removal of part of the insulator 574, part of the insulator 580, and part of an insulator 554. Since the conductor 156, the insulator 580, and the insulator 554 are formed along a side surface of the opening portion, the conductor 156, the insulator 580, and the insulator 554 are preferably formed by an ALD method or a CVD method, for example.

The conductor 156 and the conductor 160 may be formed using a conductor that can be used for a conductor 505 or the conductor 560. For example, the conductor 156 may be formed using titanium nitride by an ALD method. The conductor 160a may be formed using titanium nitride by an ALD method, and the conductor 160b may be formed using tungsten by a CVD method. Note that in the case where the adhesion of tungsten to the insulator 153 is sufficiently high, a single-layer film of tungsten formed by a CVD method may be used as the conductor 160.

As the insulator 153, an insulator of a high dielectric constant (high-k) material (material with a high relative dielectric constant) is preferably used. For the insulator of the high dielectric constant material, an oxide, an oxynitride, a nitride oxide, or a nitride containing one or more kinds of metal element selected from aluminum, hafnium, zirconium, gallium, and the like can be used, for example. The above-described oxide, oxynitride, nitride oxide, and nitride may contain silicon. For the insulator of the high dielectric constant material, insulating layers each formed of any of the above-described materials can be stacked to be used.

For the insulator of the high dielectric constant material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example. Using such a high dielectric constant material allows the insulator 153 to be thick enough to inhibit leakage current and a sufficiently high capacitance of the capacitor C to be ensured.

As the insulator 153, stacked insulating layers each formed of any of the above-described materials is preferably used, and a stacked-layer structure using a high dielectric constant material and a material having higher dielectric strength than the high dielectric constant material is preferably used. For example, as the insulator 153, an insulating film in which zirconium oxide, aluminum oxide, and zirconium oxide are stacked in this order can be used. As another example, an insulating film in which zirconium oxide, aluminum oxide, zirconium oxide, and aluminum oxide are stacked in this order can be used. As another example, an insulating film in which hafnium zirconium oxide, aluminum oxide, hafnium zirconium oxide, and aluminum oxide are stacked in this order can be used. The use of stacked insulators with relatively high dielectric strength, such as aluminum oxide, as the insulator 153 can increase the dielectric strength and inhibit electrostatic breakdown of the capacitor C.

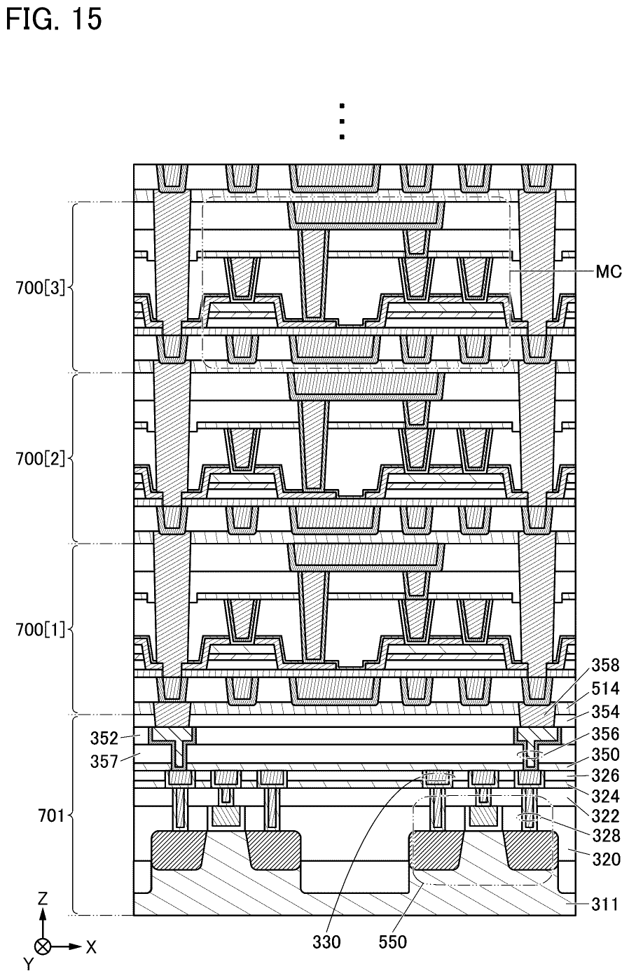

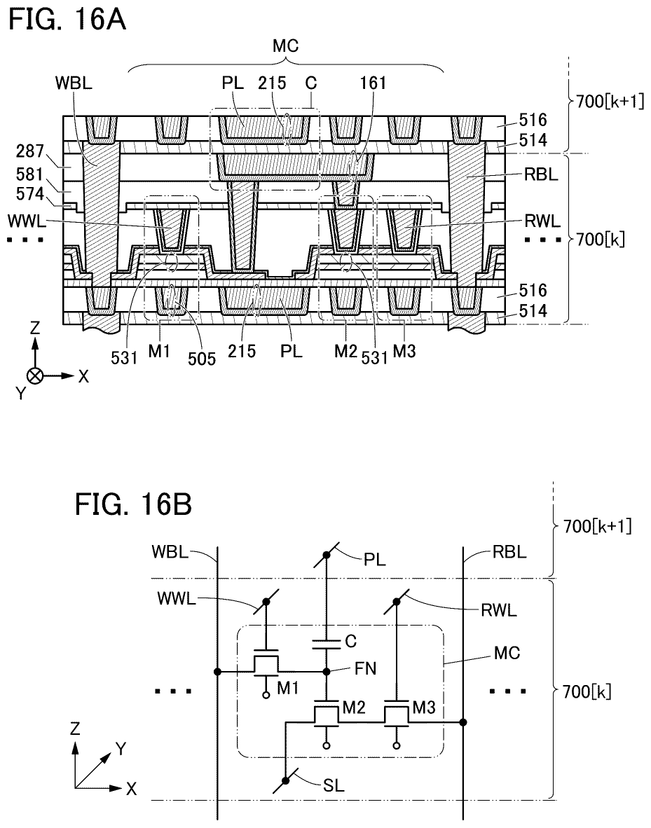

FIG. 15 illustrates a cross-sectional structure example of the case of using a NOSRAM memory cell circuit structure. FIG. 15 is also a variation example of FIG. 13. FIG. 16A illustrates a cross-sectional structure example of the memory layer 700[k]. FIG. 16B illustrates an equivalent circuit diagram of FIG. 16A.

Note that the memory cell MC illustrated in each of FIG. 15, FIG. 16A, and FIG. 16B corresponds to the memory cell MC illustrated in FIG. 5F in the above embodiment, for example. Therefore, the above description of FIG. 5F can be referred to as appropriate.

The memory cell MC illustrated in each of FIG. 15 and FIG. 16A includes the transistor M1, the transistor M2, and the transistor M3 over the insulator 514. A conductor 215 is provided to be embedded in the insulator 516 over the insulator 514. The conductor 215 can be formed using the same material in the same process as those of the conductor 505 at the same time.

The transistor M2 and the transistor M3 illustrated in FIG. 15 and FIG. 16A share one island-shaped metal oxide 531. In other words, part of the one island-shaped metal oxide 531 functions as a channel formation region of the transistor M2, and another part thereof functions as a channel formation region of the transistor M3. Furthermore, the source of the transistor M2 and the drain of the transistor M3 are shared, or the drain of the transistor M2 and the source of the transistor M3 are shared. Thus, the area occupied by the transistor M2 and the transistor M3 is smaller than that of the case where the transistor M2 and the transistor M3 are independently provided.

In the memory cell MC illustrated in each of FIG. 15 and FIG. 16A, an insulator 287 is provided over the insulator 581, and a conductor 161 is embedded in the insulator 287. The insulator 514 of the memory layer 700[k+1] is provided over the insulator 287 and the conductor 161.

A region where part of the conductor 161 in the memory layer 700[k] and part of the conductor 215 in the memory layer 700[k+1] overlap with each other with the insulator 514 therebetween functions as the capacitor C. That is, the conductor 161 of the memory layer 700[k] functions as one terminal of the capacitor C, the insulator 514 of the memory layer 700[k+1] functions as a dielectric of the capacitor C, and the conductor 215 of the memory layer 700[k+1] functions as the other terminal of the capacitor C. The one of the source and the drain of the transistor M1 is electrically connected to the conductor 161 through a contact plug, and the gate of the transistor M2 is electrically connected to the conductor 161 through another contact plug. The conductor 161 functions as the charge retention node FN. The conductor 215 is electrically connected to the wiring PL.

The other of the source and the drain of the transistor M1 is electrically connected to the bit line WBL. The gate of the transistor M1 is electrically connected to the word line WWL. The one of the source and the drain of the transistor M2 is electrically connected to the one of the source and the drain of the transistor M3 by sharing the metal oxide 531. The other of the source and the drain of the transistor M2 is electrically connected to the source line SL (not illustrated in FIG. 16A). The other of the source and the drain of the transistor M3 is electrically connected to the bit line RBL. The gate of the transistor M3 is electrically connected to the word line RWL.

This embodiment can be implemented in combination with the other embodiments and the like described in this specification and the like as appropriate.

### Embodiment 5

In this embodiment, an example of a chip including the semiconductor device of one embodiment of the present invention and an example of a module of an electronic appliance will be described.

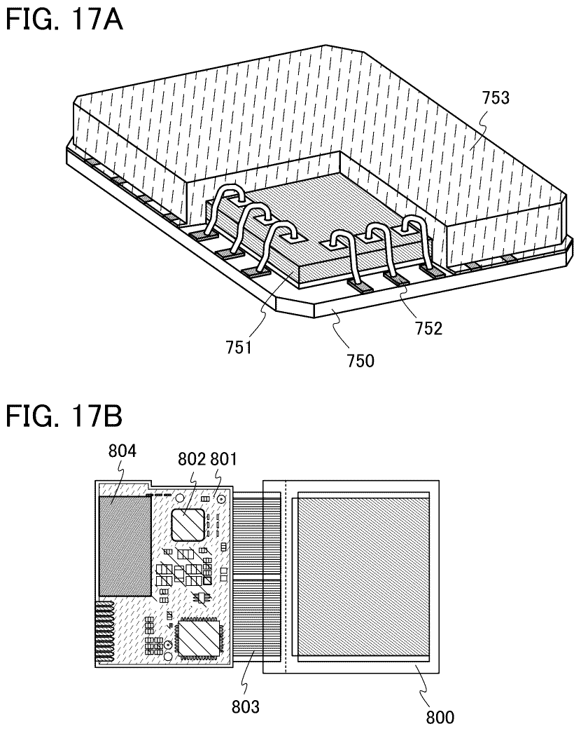

FIG. 17A illustrates a perspective view illustrating a cross-sectional structure of a package using a lead frame interposer.

In the package illustrated in FIG. 17A, a chip 751 corresponding to the semiconductor device of one embodiment of the present invention is connected to a terminal 752 over an interposer 750 by a wire bonding method. The terminal 752 is placed on a surface of the interposer 750 on which the chip 751 is mounted. The chip 751 can be sealed by a mold resin 753, in which case the chip 751 is sealed so that part of each of the terminals 752 is exposed.

FIG. 17B illustrates a structure of a module of an electronic appliance in which the package is mounted on a circuit board.

In the module illustrated in FIG. 17B, a package 802 and a battery 804 are mounted on a printed wiring board 801. In addition, the printed wiring board 801 is mounted on a panel 800 including a display element by an FPC 803.

The structures and the like described above in this embodiment can be used in combination with the structures and the like described in the other embodiments and the like as appropriate.

### Embodiment 6

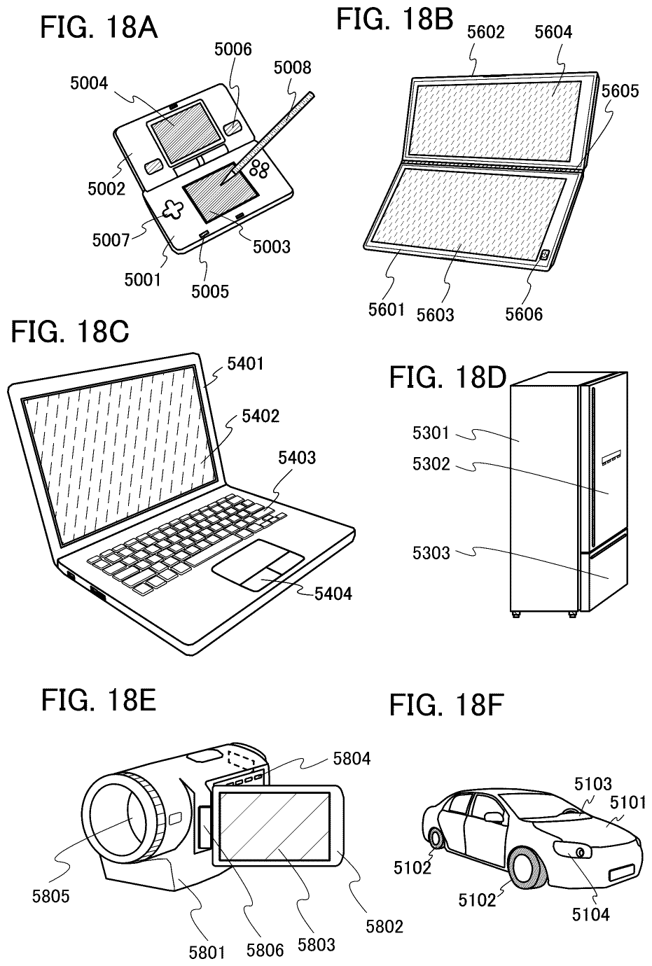

A semiconductor device of one embodiment of the present invention can be used for a display appliance, a personal computer, or an image reproducing device provided with recording media (typically, a device that reproduces the content of recording media such as a DVD (digital versatile disc) and has a display for displaying the reproduced image). Other examples of electronic apparatuses that can use the semiconductor device of one embodiment of the present invention are mobile phones, game consoles including portable game consoles, portable information terminals, e-book readers, cameras (e.g., video cameras and digital still cameras), goggles-type displays (head mounted displays), navigation systems, audio reproducing devices (e.g., car audio units and digital audio players), copiers, facsimiles, printers, multifunction printers, automated teller machines (ATM), and vending machines. FIG. 18A to FIG. 18F illustrate specific examples of such electronic apparatuses.

FIG. 18A illustrates a portable game console that includes a housing 5001, a housing 5002, a display portion 5003, a display portion 5004, a microphone 5005, a speaker 5006, an operation key 5007, a stylus 5008, and the like, for example. The semiconductor device of one embodiment of the present invention can be used for a variety of integrated circuits included in a portable game console. Note that although the portable game console illustrated in FIG. 18A has the two display portion 5003 and display portion 5004, the number of display portions included in the portable game console is not limited thereto.

FIG. 18B illustrates a portable information terminal that includes a first housing 5601, a second housing 5602, a first display portion 5603, a second display portion 5604, a joint 5605, an operation key 5606, and the like, for example. The first display portion 5603 is provided in the first housing 5601, and the second display portion 5604 is provided in the second housing 5602. Furthermore, the first housing 5601 and the second housing 5602 are connected to each other with the joint 5605, and the angle between the first housing 5601 and the second housing 5602 can be changed with the joint 5605. Images on the first display portion 5603 may be changed in accordance with the angle at the joint 5605 between the first housing 5601 and the second housing 5602. The semiconductor device of one embodiment of the present invention can be used for a variety of integrated circuits included in a portable information terminal. Moreover, a display apparatus to which a function of a position input device is added may be used as at least one of the first display portion 5603 and the second display portion 5604. Note that the function of the position input device can be added through providing a touch panel to a display apparatus. Alternatively, the function of the position input device can be added through providing a photoelectric conversion element called a photosensor in a pixel portion of a display apparatus.

FIG. 18C illustrates a laptop personal computer that includes a housing 5401, a display portion 5402, a keyboard 5403, a pointing device 5404, and the like, for example. The semiconductor device of one embodiment of the present invention can be used for a variety of integrated circuits included in a laptop personal computer.

FIG. 18D illustrates an electric refrigerator-freezer that includes a housing 5301, a refrigerator door 5302, a freezer door 5303, and the like, for example. The semiconductor device of one embodiment of the present invention can be used for a variety of integrated circuits included in an electric refrigerator-freezer.

FIG. 18E illustrates a video camera that includes a first housing 5801, a second housing 5802, a display portion 5803, operation keys 5804, a lens 5805, a joint 5806, and the like, for example. The operation keys 5804 and the lens 5805 are provided in the first housing 5801, and the display portion 5803 is provided in the second housing 5802. The semiconductor device of one embodiment of the present invention can be used for a variety of integrated circuits included in a video camera. Furthermore, the first housing 5801 and the second housing 5802 are connected to each other with the joint 5806, and the angle between the first housing 5801 and the second housing 5802 can be changed with the joint 5806. Images on the display portion 5803 may be changed in accordance with the angle at the joint 5806 between the first housing 5801 and the second housing 5802.

FIG. 18F illustrates an automobile that includes a car body 5101, wheels 5102, a dashboard 5103, lights 5104, and the like, for example. The semiconductor device of one embodiment of the present invention can be used for a variety of integrated circuits included in an automobile.

The structures, configurations, methods, and the like described in this embodiment can be used in combination as appropriate with the structures, configurations, methods, and the like described in the other embodiments and the like.

### REFERENCE NUMERALS

100: semiconductor device, 111: first cache, 112: second cache, 113: cache portion, 114: cache controller, 115: core, 116: thermal detector, 117: bus, 121: memory controller, 122: power controller, 123: clock controller, 131: temperature sensor, 141: memory, SW11: switch, SW12: switch, SW13: switch, SW14: switch, SW15: switch, SW16: switch, SW17: switch, SW18: switch, ADDR: signal, DATA: signal, HIT: signal, MEM1_EN: signal, MEM2_EN: signal, MEM1_PW: signal, MEM2_PW: signal, VSS: potential, VDD: potential, M11: transistor, M12: transistor, M13: transistor, M14: transistor, M15: transistor, M16: transistor, M17: transistor, M18: transistor, 300: memory device, 21: memory cell portion, 90: memory cell array, MC: memory cell, 22: driver circuit portion, 62: PSW, 63: PSW, 71: peripheral circuit, 72: control circuit, 73: voltage generation circuit, 81: peripheral circuit, 82: row decoder, 83: row driver, 84: column decoder, 85: column driver, 87: input circuit, 88: output circuit, 51: driver circuit, 55: sense amplifier, WDA: signal, RDA: signal, BW: signal, CE: signal, GW: signal, CLK: signal, WAKE: signal, PON1: signal, PON2: signal, Din: data, Dout: data, VHM: potential, 91: word line driver circuit, 92: bit line driver circuit, M1: transistor, M2: transistor, M3: transistor, C: capacitor, FN: charge retention node, CL: capacitor line, WL: word line, WWL: word line, RWL: word line, BL: bit line, WBL: bit line, RBL: bit line, BGL: back gate line, S01: step, S02: step, S03: step, S04: step, S05: step, S06: step, S07: step, S08: step, S09: step, S10: step, S11: step, S21: step, S31: step, S41: step, S42: step, S43: step, S51: step, S52: step, S53: step, 170: semiconductor device, 171: substrate, 180: die, 181: memory region, 182: memory layer, 185: core region, 172: via hole, 173: electrode, 174: electrode, 175: plug, 311: substrate, 500: transistor, 550: transistor, 600: capacitor

1. A semiconductor device comprising a first cache, a second cache, a cache controller, and a core,
wherein the core is configured to perform program processing,
wherein the cache controller is configured to perform control to store data for performing the program processing in the second cache in the case where a temperature around or inside the core is higher than or equal to a predetermined temperature threshold value, and
wherein the cache controller is configured to perform control to store the data for performing the program processing in the first cache in the case where the temperature around or inside the core is lower than the predetermined temperature threshold value.

2. The semiconductor device according to claim 1,
wherein the first cache comprises a Si transistor, and
wherein the second cache comprises an OS transistor.

3. The semiconductor device according to claim 2, further comprising a substrate, a layer over the substrate, and a die over the substrate,
wherein the core is provided over the substrate,
wherein part of the first cache is provided in the layer,
wherein part of the second cache is provided in the die,
wherein the layer is electrically connected to the substrate through a via hole formed between the substrate and the layer, and
wherein the die is electrically connected to the substrate by bonding a first electrode formed on the substrate and a second electrode formed on the die to each other.

4. The semiconductor device according to claim 2, further comprising a substrate, a layer over the substrate, and a die over the layer,
wherein the core is provided over the substrate,
wherein part of the first cache is provided in the layer,
wherein part of the second cache is provided in the die,
wherein the layer is electrically connected to the substrate through a via hole formed between the substrate and the layer, and
wherein the die is electrically connected to the layer by bonding a first electrode formed on the layer and a second electrode formed on the die to each other.
